(19) United States
(12) Patent Application Publication
(10) Pub. No.: US 2026/0026245 A1
(43) Pub. Date: Jan. 22, 2026

(54) DISPLAY DEVICE

(71) Applicant: LG Display Co., Ltd., Seoul (KR)

(72) Inventors: Surin Han, Paju-si (KR); Jonghyun Han, Paju-si (KR); Seongwoong Jeong, Paju-si (KR); Younggyu Moon, Paju-si (KR)

(73) Assignee: LG Display Co., Ltd., Seoul (KR)

(21) Appl. No.: 19/192,933

(22) Filed: Apr. 29, 2025

(30) Foreign Application Priority Data
Jul. 17, 2024 (KR) 10-2024-0094588

(51) Int. Cl. H10K 59/80; H10K 59/38; H10K 59/40

(52) U.S. Cl. CPC H10K 59/873; H10K 59/38; H10K 59/40

(57) ABSTRACT

Exemplary embodiments of the disclosure relate to a display device and, more specifically, may include a substrate, a light emitting element, a first inorganic layer, a first organic layer, a second inorganic layer, an inner dam portion, a black matrix, a plurality of color filters, an overcoat layer, a second organic layer, and an outer dam portion disposed outside the second organic layer and including a material included in the overcoat layer, preventing the organic layer from overflowing.

### CROSS-REFERENCE TO RELATED APPLICATION

This application claims priority from and benefit of Korean Patent Application No. 10-2024-0094588, filed on Jul. 17, 2024, which is hereby incorporated by reference in its entirety for all purposes as if fully set forth herein.

### TECHNICAL FIELD

Exemplary embodiments of the disclosure relate to a display device.

### DISCUSSION OF THE RELATED ART

As the information society develops, demand for display devices for displaying images is increasing in various forms. Various display devices, such as liquid crystal display devices and organic light emitting display devices, are being utilized in recent years.

Organic layers may be disposed inside the display panel. The organic layer may protect components disposed inside the organic layer from the outside of the organic layer.

Since the organic layer has flowability, a dam may be placed on the outside of the organic layer. The dam may reduce or prevent the organic layer from flowing away from a specific area.

The description provided in the background section should not be assumed to be prior art merely because it is mentioned in or associated with the background section. The background section may include information that describes one or more aspects of the subject technology.

### SUMMARY

Accordingly, embodiments of the present disclosure are directed to a display device that substantially obviates one or more of the problems due to limitations and disadvantages of the related art.

An aspect of the present disclosure is to provide a display device capable of reducing or preventing an organic layer from overflowing.

Another aspect of the present disclosure is to provide a display device capable of reducing or preventing a first organic layer from overflowing and preventing a second organic layer disposed on the first organic layer from overflowing by disposing a dam.

Another aspect of the present disclosure is to provide a display device capable of process optimization by disposing a dam capable of preventing an organic layer from overflowing.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a display area and a non-display area outside the display area, a light emitting element disposed on the substrate, a first inorganic layer disposed on the light emitting element, a first organic layer disposed on the first inorganic layer, a second inorganic layer disposed on the first organic layer and extending to a side surface of the first organic layer, an inner dam portion disposed on the substrate, disposed outside the first organic layer, and disposed under at least one of the first inorganic layer and the second inorganic layer, a black matrix disposed on the second inorganic layer, a plurality of color filters disposed on the second inorganic layer, an overcoat layer disposed on the black matrix and the plurality of color filters, a second organic layer disposed on the overcoat layer and extending to an upper portion of the inner dam portion, and an outer dam portion disposed outside the second organic layer and including a material included in the overcoat layer.

In another aspect, a display device comprises a substrate including a display area and a non-display area outside the display area, a light emitting element disposed on the substrate, a plurality of encapsulation layers disposed on the light emitting element, an inner dam portion disposed in the non-display area, and an outer dam portion disposed in the non-display area and disposed further outside than the inner dam portion, wherein at least one of the plurality of encapsulation layers may be disposed to extend to an upper portion of the inner dam portion and a lower portion of the outer dam portion.

According to exemplary embodiments of the disclosure, there may be provided a display device capable of preventing an organic layer from overflowing through a dam.

According to exemplary embodiments of the disclosure, there may be provided a display device capable of preventing a first organic layer from overflowing and preventing a second organic layer disposed on the first organic layer from overflowing through a dam.

According to exemplary embodiments of the disclosure, there may be provided a display device capable of process optimization by disposing a dam capable of preventing an organic layer from overflowing.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a view illustrating a system configuration of a display device according to exemplary embodiments of the disclosure;

FIG. 2 illustrates a display panel according to an embodiment of the disclosure;

FIG. 3 illustrates a display panel where an optical device is disposed according to exemplary embodiments of the disclosure;

FIG. 4 is a plan view illustrating a display panel including an encapsulation layer and a dam according to exemplary embodiments of the disclosure;

FIG. 5 is a cross-sectional view illustrating a C-D area of a display panel as illustrated in FIG. 4;

FIGS. 6 and 7 are cross-sectional views of a display panel, illustrating an outer dam portion including a single material according to exemplary embodiments of the disclosure;

FIGS. 8 and 9 are cross-sectional views of a display panel, illustrating an outer dam portion including two materials according to exemplary embodiments of the disclosure;

FIGS. 10 and 11 are cross-sectional views of a display panel, illustrating an outer dam portion including three materials according to exemplary embodiments of the disclosure;

FIGS. 12 and 13 are cross-sectional views illustrating a display panel including a recess according to exemplary embodiments of the disclosure; and

FIG. 14 is a cross-sectional view illustrating an E-F area of a display panel as illustrated in FIG. 4.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or exemplary embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or exemplary embodiments of the disclosure, detailed descriptions of well-known functions and components incorporated herein will be omitted when it is determined that the description may make the subject matter in some exemplary embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

A shape (e.g., sizes, lengths, widths, heights, thicknesses, locations, radii, diameters, and areas), a ratio, an angle, and a number disclosed in the drawings for describing embodiments of the present disclosure are merely an example, and thus, the present disclosure is not limited to the illustrated details. Like reference numerals refer to like elements throughout the disclosure.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements. Any implementation described herein as an “example” is not necessarily to be construed as preferred or advantageous over other implementations.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

The terms, such as “below,” “lower,” “above,” “upper” and the like, may be used herein to describe a relationship between element(s) as illustrated in the drawings. It will be understood that the terms are spatially relative and based on the orientation depicted in the drawings.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”. Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Hereinafter, various exemplary embodiments of the disclosure are described in detail with reference to the accompanying drawings.

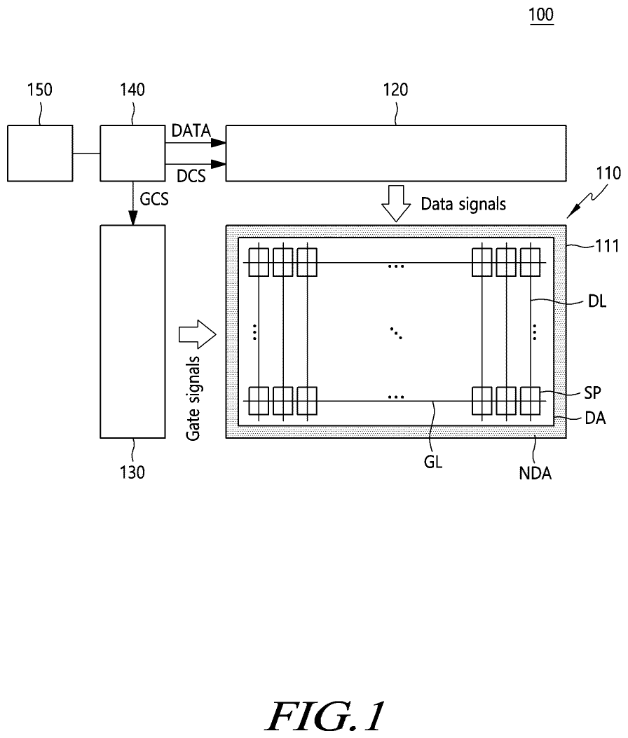

FIG. 1 is a view illustrating a system configuration of a display device according to exemplary embodiments of the disclosure.

Referring to FIG. 1, a display device 100 according to exemplary embodiments of the disclosure may include a display panel 110 and display driving circuits, as components for displaying images. The display driving circuit may be a circuit for driving the display panel 110. The display driving circuits may include a data driving circuit 120, a gate driving circuit 130, and a controller 140, but embodiments of the disclosure are not limited thereto.

The display panel 110 may include a substrate 111 and a plurality of subpixels SP disposed on the substrate 111.

The substrate 111 may include a display area DA capable of image display and a non-display area NDA positioned outside the display area DA. As an example, the non-display area NDA may fully or partially surround the display area DA. A plurality of subpixels SP for image display may be disposed in the display area DA. As an example, the non-display area NDA may include a pad area PA. As an example, the non-display area NDA may include a pad area PA positioned in a column direction from the display area DA, without being limited thereto.

Various types of signal lines for driving a plurality of subpixels SP may be disposed on the substrate 111 of the display panel 110.

The display device 100 according to exemplary embodiments of the disclosure may be an organic light emitting display device, an inorganic light emitting display device, a quantum dot display device, a micro LED display device, or a mini LED display device, etc.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors, but embodiments of the disclosure are not limited thereto.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the column direction. Each of the plurality of gate lines GL may be disposed to extend in the row direction. According to exemplary embodiments of the disclosure, the column direction and the row direction may be relative directions.

The data driving circuit 120 may be a circuit for driving a plurality of data lines DL. The data driving circuit 120 may output data signals to the plurality of data lines DL.

The data driving circuit 120 may receive digital image data DATA from the controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but embodiments of the disclosure are not limited thereto.

The data driving circuit 120 may be connected to one side (e.g., an upper or lower side) of the display panel 110. As another example, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but as another example, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to exemplary embodiments of the disclosure, the gate driving circuit 130 may be embedded, in a gate in panel (GIP) type, in the display panel 110, but embodiments of the disclosure are not limited thereto. When the gate driving circuit 130 is of the gate in panel type, the gate driving circuit 130 may be formed on the substrate 111 of the display panel 110 during the manufacturing process of the display panel 110.

For example, the gate driving circuit 130 may be disposed in the non-active area NDA of the display panel 110. As another example, the gate driving circuit 130 may be disposed in the display area DA of the display panel 110. Embodiments are not limited thereto. As an example, the gate driving circuit 130 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110, but embodiments of the disclosure are not limited thereto.

The controller 140 is a device for controlling the data driving circuit 120 and the gate driving circuit 130 and may control driving timings for the plurality of data lines DL and driving timings for the plurality of gate lines GL.

The controller 140 may supply a data driving control signal DCS to the data driving circuit 120 to control the data driving circuit 120 and may supply a gate driving control signal GCS to the gate driving circuit 130 to control the gate driving circuit 130.

The controller 140 may receive input image data from the host system 150 and supply image data DATA to the data driving circuit 120 based on the input image data.

The controller 140 may be a timing controller used in display technology, a control device that may perform other control functions as well as the functions of the timing controller, or a control device other than the timing controller, or may be a circuit in the control device.

As an example, the controller 140 may be mounted on a printed circuit board or a flexible printed circuit and may be electrically connected with the data driving circuit 120 and the gate driving circuit 130 through the printed circuit board or the flexible printed circuit, without being limited thereto.

To provide a touch sensing function as well as an image display function, as an example, the display device 100 according to exemplary embodiments of the disclosure may include a touch sensor and a touch sensing circuit that senses the touch sensor to detect whether a touch occurs by a touch object, such as a finger or pen, or the position of the touch, without being limited thereto.

The touch sensing circuit may include a touch driving circuit that drives and senses the touch sensor and generates and outputs touch sensing data and a touch controller that may detect an occurrence of a touch or the position of the touch using the touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is of an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, as an example, the touch sensor may be formed on the substrate, together with signal lines and electrodes related to display driving, during the manufacturing process of the display panel 110, without being limited thereto.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit. The power supply circuit may supply various voltages and power voltages related to display driving to the display driving circuit or display panel 110.

The display device 100 according to exemplary embodiments of the disclosure may be a mobile terminal, such as a smart phone or a tablet, or a monitor or television (TV) in various sizes but, without limited thereto, may be a display in various types and various sizes capable of displaying information or images.

The display device 100 according to exemplary embodiments of the disclosure may further include an electronic device such as a camera (image sensor), a detection sensor, or the like, without being limited thereto. For example, the detection sensor may be a sensor that detects an object or a human body by receiving light such as infrared rays, ultrasonic waves, or ultraviolet rays, but embodiments of the disclosure are not limited thereto.

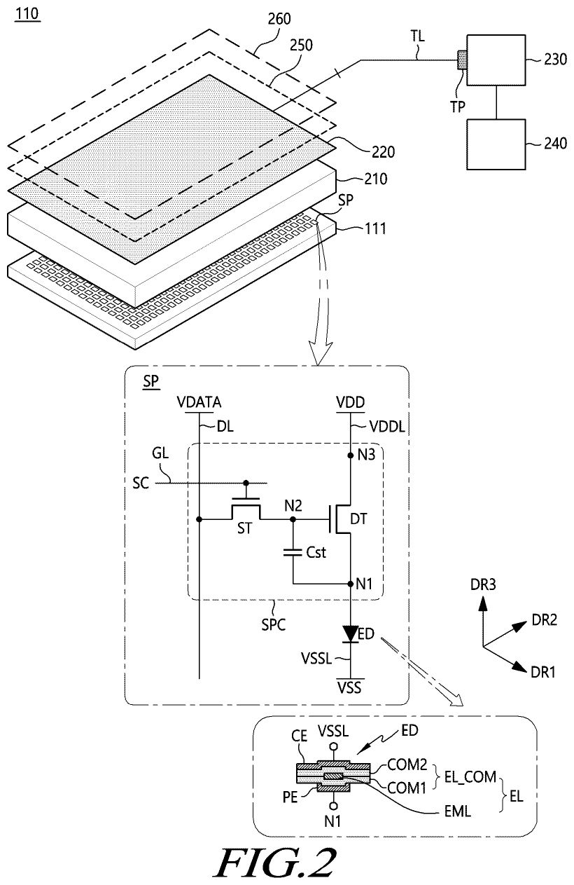

FIG. 2 is a view illustrating a display panel 110 according to an exemplary embodiment of the disclosure.

Referring to FIG. 2, the display panel 110 may include a substrate 111 on which a plurality of subpixels SP is disposed and a first encapsulation layer 210 on the substrate 111. The first encapsulation layer 210 may also be referred to as an encapsulation substrate or an encapsulation unit.

Referring to FIG. 2, when the display device 100 according to exemplary embodiments of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED, but embodiments of the disclosure are not limited thereto. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT. The gate node of the scan transistor ST may be electrically connected to the gate line GL.

The at least one capacitor may include a storage capacitor Cst for maintaining a constant voltage during a certain period (e.g., a frame).

To drive the subpixel SP, a data signal VDATA as an image signal and a scan signal SC as a gate signal may be applied to the subpixel SP. Further, for driving the subpixel SP, a common pixel driving voltage including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode. Embodiments are not limited thereto. As an example, the pixel electrode PE may be an electrode disposed in all or some subpixels SP, and/or the common electrode CE may be an electrode separately disposed in each subpixels SP. As an example, either of the pixel electrode PE and the common electrode CE may be an electrode separately disposed in each subpixels SP, without being limited thereto.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM. Embodiments are not limited thereto. As an example, at least one of the first common intermediate layer COM1 and the second common intermediate layer COM2 may be omitted depending on the design.

As an example, the light emitting layer EML may be disposed for each subpixel SP, without being limited thereto. The common intermediate layer EL_COM may be commonly disposed across the plurality of subpixels SP, but embodiments of the disclosure are not limited thereto. As an example, the light emitting layer EML may be commonly disposed across at least some subpixels SP, and/or the common intermediate layer EL_COM may be disposed for each subpixel SP, without being limited thereto.

As an example, the light emitting layer EML may be disposed for each emission area, without being limited thereto. The common intermediate layer EL_COM may be commonly disposed across a plurality of emission areas and non-emission areas, but embodiments of the disclosure are not limited thereto.

For example, the first common intermediate layer COM1 may include a hole injection layer HIL, an electron blocking layer EBL, and a hole transport layer HTL, but embodiments of the disclosure are not limited thereto. The second common intermediate layer COM2 may include an electron transport layer ETL, a hole blocking layer HBL, and an electron injection layer EIL, but embodiments of the disclosure are not limited thereto.

The hole injection layer may inject holes from the pixel electrode PE to the hole transport layer, the hole transport layer may transport the holes to the light emitting layer EML, the electron injection layer may inject electrons from the common electrode CE to the electron transport layer, and the electron transport layer may transport electrons to the light emitting layer EML.

For example, the common electrode CE may be electrically connected to the base voltage line VSSL. The base voltage VSS, which is one type of the common pixel driving voltage, may be applied to the common electrode CE through the base voltage line VSSL. The pixel electrode PE may be electrically connected directly or indirectly (e.g., through another transistor) to the first node N1 of the driving transistor DT of each subpixel SP. In the disclosure, “base voltage VSS” may also be referred to as a “low-potential power voltage” or a “low-potential voltage,” and “base voltage line VSSL” may also be referred to as a “low-potential power voltage line” or a “low-potential voltage line.”

Each light emitting element ED may include portions where the pixel electrode PE, the light emitting layer in the intermediate layer LE, and the common electrode CE overlap. A predetermined light emitting area may be formed by each light emitting element ED. For example, the light emitting area of each light emitting element ED may include an overlapping area of the pixel electrode PE, the intermediate layer EL, and the common electrode CE.

For example, the light emitting element ED may be an organic light emitting diode (OLED), an inorganic light emitting diode (LED), a quantum dot light emitting element, a micro LED, or a mini LED, but embodiments of the disclosure are not limited thereto. For example, when the light emitting element ED is an organic light emitting diode (OLED), the intermediate layer EL of the light emitting element ED may include an intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node N1, a second node N2, and a third node N3. The first node N1 may be electrically connected to the light emitting element ED, the second node N2 may receive a data signal VDATA, and the third node N3 may receive a driving voltage VDD from the driving voltage line VDDL. The driving transistor DT may be connected to the first node N1 and the third node N3.

In the driving transistor DT, the second node N2 may be a gate node, the first node N1 may be a source node or a drain node, and the third node N3 may be a drain node or a source node. Hereinafter, for convenience of description, an example is described in which in the driving transistor DT, the second node N2 may be a gate node, the first node N1 may be a source node, and the third node N3 may be a drain node, but embodiments of the disclosure are not limited thereto.

The scan transistor ST included in the subpixel circuit SPC illustrated in FIG. 2 may be a switching transistor for transferring the data signal VDATA, which is an image signal, to the second node N2, which is the gate node of the driving transistor DT.

The scan transistor ST may be controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT, but embodiments of the disclosure are not limited thereto.

Each of the driving transistor DT and the scan transistor ST may be an n-type transistor or a p-type transistor, but embodiments of the disclosure are not limited thereto. For example, one of the driving transistor DT and the scan transistor ST may be either an n-type transistor or a p-type transistor.

The display panel 110 may have a top emission structure, a bottom emission structure, or a dual emission structure.

When the display panel 110 has a top emission structure, as an example, at least a portion of the subpixel circuit SPC may overlap at least a portion of the light emitting element ED in a vertical direction. Accordingly, the area of the emission area may increase and the aperture ratio may increase. Embodiments of the disclosure are not limited thereto. As an example, even if the display panel 110 has a top emission structure, the subpixel circuit SPC may still not overlap the light emitting element ED in the vertical direction.

When the display panel 110 has a bottom emission structure, as an example, the subpixel circuit SPC may not overlap the light emitting element ED in the vertical direction. Alternatively, a portion of the subpixel circuit SPC may overlap the light emitting element ED in the vertical direction.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors. As an example, the configuration of the subpixel circuit SPC may be varied in various ways.

For example, the subpixel circuit SPC may have an 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP may vary. Further, the type and the number of common pixel driving voltages supplied to the subpixel SP may vary according to the structure of the subpixel circuit SPC.

Since the circuit elements (e.g., the light emitting element ED implemented as an organic light emitting diode (OLED) including an organic material) in each subpixel SP are vulnerable to external moisture or oxygen, the first encapsulation layer 210 may be disposed on the display panel 110. The first encapsulation layer 210 may reduce or prevent external moisture or oxygen from penetrating into circuit elements (e.g., the light emitting element ED). The first encapsulation layer 210 may be configured in various forms so that the light emitting elements ED do not or less contact moisture or oxygen. For example, the first encapsulation layer 210 may be constituted of two or more layers in which organic films and inorganic films are alternately stacked, but embodiments of the disclosure are not limited thereto.

Referring to FIG. 2, a display device 100 according to exemplary embodiments of the disclosure may include a touch sensor layer 220 including a plurality of sensor electrodes to sense the user's touch, a touch driving circuit 230 configured to sense the plurality of sensor electrodes, and a touch controller 240 configured to determine the presence or absence of a touch or touch coordinates using the sensing result (touch sensing data) of the touch driving circuit 230. Embodiments of the disclosure are not limited thereto. As an example, the touch sensor layer 220 may be omitted depending on the design.

The touch sensor layer 220 may be embedded in the display panel 110. For example, the touch sensor layer 210 may be disposed on the first encapsulation layer 210 in the display panel 110. The touch sensor layer 220 may be a touch unit.

The display panel 110 may further include a plurality of touch pads TP electrically connected to the touch driving circuit 230 and a plurality of touch routing lines for electrically connecting the plurality of sensor electrodes included in the touch sensor layer 220 to the plurality of touch pads TP connected to the touch driving circuit 230.

As an example, a color filter layer 250 may be disposed on the touch sensor layer 220, without being limited thereto. The color filter layer 250 may convert a color of light passing through the color filter layer 250. As an example, the color filter layer 250 may be disposed on a layer other than the touch sensor layer 220, or may be omitted depending on the design.

As an example, the color filter layer 250 may include a plurality of color filters and/or a black matrix. The plurality of color filters may be formed by a pigment method or a dye method. The plurality of color filters may convert the color of light passing through the plurality of color filters. As an example, the plurality of color filters may include a red color filter, a green color filter, and a blue color filter, without being limited thereto. As an example, the plurality of color filters may include a color filter of other colors, without being limited thereto. The black matrix may reduce or prevent mixing of light passing through the plurality of color filters.

As an example, the color filter layer 250 may further include an insulation layer disposed under the black matrix. The insulation layer may be a color filter buffer layer. The insulation layer may include an inorganic material. As an example, the insulation layer may be omitted depending on the design.

As an example, the color filter layer 250 may further include an insulation layer disposed on the color filter, without being limited thereto. The insulation layer may be an overcoat layer. As an example, the insulation layer may include an organic material, without being limited thereto.

As an example, the second organic encapsulation layer 260 may be disposed on the color filter layer 250. The second organic encapsulation layer 260 may include an organic material. Hereinafter, the second organic encapsulation layer 260 is described in more detail.

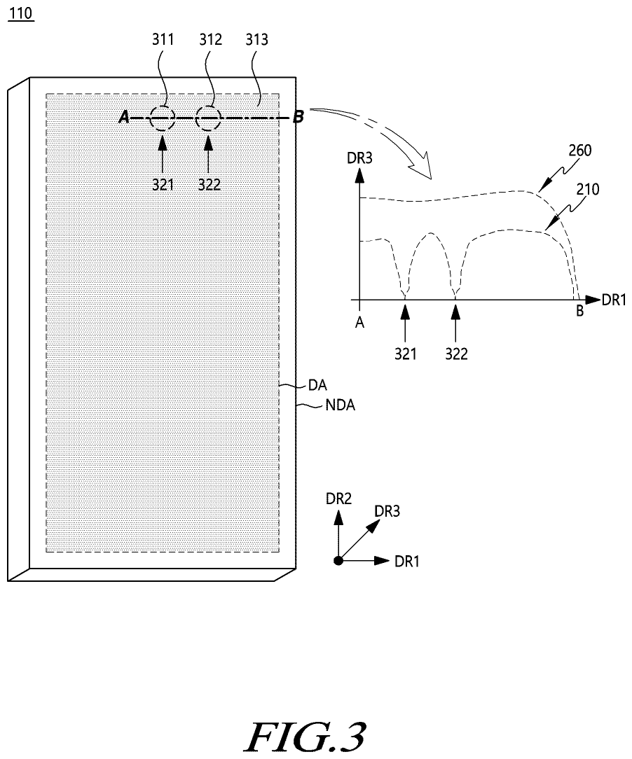

FIG. 3 illustrates a display panel where an optical device is disposed according to exemplary embodiments of the disclosure.

The display panel 110 may include a display area DA and a non-display area NDA.

Referring to FIG. 3, as an example, the display area DA may include optical areas 311 and 312 and a normal area 313. Embodiments are not limited thereto. As an example, the display area DA may include one, three or more optical areas, or may not include any optical area.

The normal area 313 may be an area in which an image is displayed.

The optical areas 311 and 312 may be areas in which the optical device is disposed. The optical device may be a camera, an infrared sensor, an illuminance sensor, or an ultrasonic sensor, without being limited thereto.

The optical areas 311 and 312 may have a circular shape, but are not limited thereto. As an example, the optical areas 311 and 312 may have a rounded shape, a triangle shape, a rectangular shape, an oval shape, a polygonal shape, etc.

There may be one or more optical areas 311 and 312. For example, the number of optical areas 311 and 312 may be two, and the optical areas 311 and 312 may include a first optical area 311 and a second optical area 312.

A first optical device may be disposed in the first optical area 311, and a second optical device may be disposed in the second optical area 312. Embodiments are not limited thereto. As an example, two or more optical device may be disposed in one optical area.

Referring to FIG. 3, graphs of heights of the first encapsulation layer 210 and the second organic encapsulation layer 260 may be identified. The horizontal axis of the graph represents the first direction DR1, and the vertical axis represents the third direction DR3. The first direction DR1 and the second direction DR3 are horizontal and vertical directions, and the third direction DR3 represents a vertical direction.

The graph shown in FIG. 3 shows the heights of the first encapsulation layer 210 and the second organic encapsulation layer 260 in the area A-B of the display panel 110.

Referring to the graph shown in FIG. 3, it may be identified that the first encapsulation layer 210 is decreased from the central position 321 of the first optical area 311 and the central position 322 of the second optical area 312. For this reason, when an image is displayed on the display panel 110, a stain may be generated around the optical areas 311 and 312.

In order to reduce or prevent the above-described stain, the second organic encapsulation layer 260 may be disposed on the first encapsulation layer 210. Referring to the graph shown in FIG. 3, the second organic encapsulation layer 260 may be disposed to maintain a height of a predetermined range and, in the non-display area NDA, have an inclination.

As an example, the second organic encapsulation layer 260 may include an organic material, without being limited thereto. Therefore, the second organic encapsulation layer 260 may have a property of easily flowing. In order to reduce or prevent the second organic encapsulation layer 260 from deviating from a specific position, a dam may be disposed outside the second organic encapsulation layer 260. Hereinafter, a dam disposed outside the second organic encapsulation layer 260 is described.

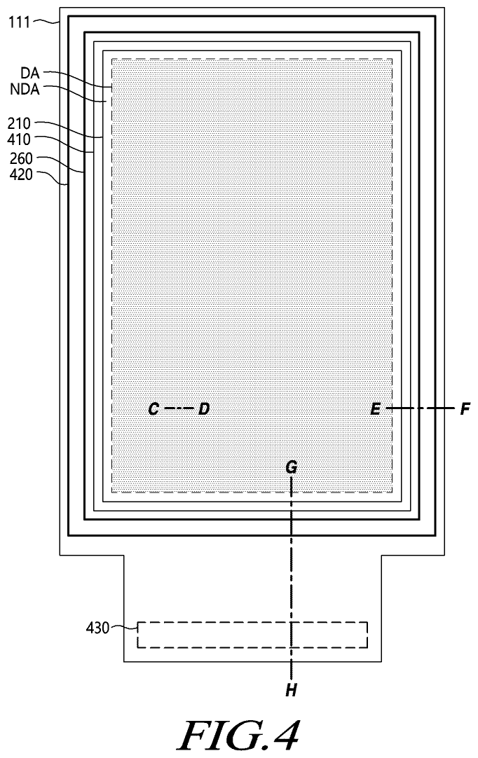

FIG. 4 is a plan view illustrating a display panel including encapsulation layers 210 and 260 and dams 410 and 420 according to exemplary embodiments of the disclosure.

Referring to FIG. 4, the substrate 111 may include a display area DA and a non-display area NDA. The non-display area NDA may include a pad area 430. The pad area 430 may be an area in which the display panel 110 is electrically connected to an external circuit. The pad area 430 may be an area in which the display panel 110 is physically connected to an external circuit.

The first encapsulation layer 210 may be disposed on the display area DA. The first encapsulation layer 210 may be disposed up to the outside of the display area DA.

The inner dam portion 410 may be disposed outside the first encapsulation layer 210. The inner dam portion 410 may be disposed to surround the first encapsulation layer 210. The inner dam portion 410 may be disposed to reduce or prevent overflow of the first encapsulation layer 210.

The second organic encapsulation layer 260 may be disposed on the display area DA. The second organic encapsulation layer 260 may be disposed up to the outside of the display area DA. Referring to FIG. 4, the second organic encapsulation layer 260 may be disposed outside the inner dam portion 410. However, depending on the design, the positions of the second organic encapsulation layer 260 and the inner dam portion 410 may be irrelevant to each other.

The outer dam portion 420 may be disposed outside the second organic encapsulation layer 260. The outer dam portion 420 may be disposed to surround the second organic encapsulation layer 260. The outer dam portion 420 may be disposed to reduce or prevent overflow of the second organic encapsulation layer 260.

Referring to FIG. 4, a C-D area, an E-F area, and a G-H area may be identified. Hereinafter, a cross-sectional structure of the display panel 110 is described through cross-sectional views of corresponding areas.

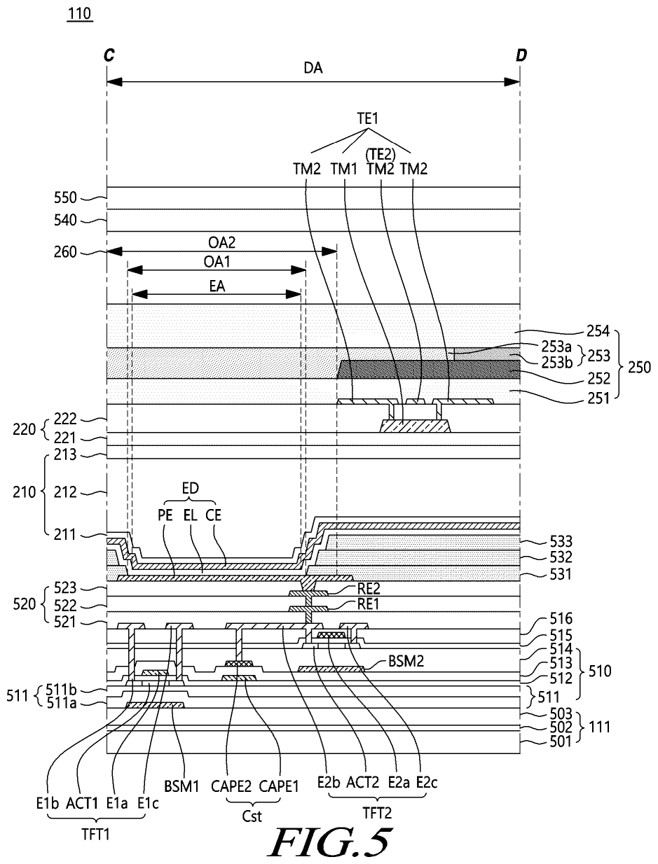

FIG. 5 is a cross-sectional view illustrating a C-D area of a display panel 110 as illustrated in FIG. 4.

Referring to FIG. 5, the display panel 110 according to exemplary embodiments of the disclosure may include a transistor unit, a light emitting element unit, and an encapsulation unit, but embodiments of the disclosure are not limited thereto.

The substrate 111 may be a single layer or multiple layers. When the substrate 111 includes multiple layers, the substrate 111 may include a first substrate 501, an intermediate layer 502, and a second substrate 503, without being limited thereto. The intermediate layer 502 may be positioned between the first substrate 501 and the second substrate 503. For example, each of the first substrate 501 and the second substrate 503 may be a polyimide (PI) layer, but embodiments of the disclosure are not limited thereto. The intermediate layer 502 may be an inorganic insulation layer, but embodiments of the disclosure are not limited thereto. When an electric charge is charged to the first substrate 501 which is a polyimide layer, the intermediate layer 502 may reduce or prevent the electric charge from affecting transistors disposed on the second substrate 503 through the second substrate 503 which is a polyimide layer.

Further, the intermediate layer 502 may reduce or prevent a moisture component from penetrating upward through the first substrate 501. For example, the intermediate layer 502 may be formed of a single layer of silicon nitride (SiNx) or silicon oxide (SiOx) or multiple layers thereof, or may be formed of a double layer or a multiple layer of silicon dioxide (SiO₂) and silicon nitride (SiNx), but is not limited thereto.

The transistor unit may include a substrate 111, an insulation layer 510, 511, 512, 513, 514, 515, and 516 on the substrate 111, thin film transistors TFT1 and TFT2, a storage capacitor Cst, and various electrodes or signal lines. Embodiments are not limited thereto. As an example, one or more of the above-mentioned layers or components may be omitted depending on the design, one or more additional layers or components may be further included.

The thin film transistors TFT1 and TFT2 included in the transistor unit may include a first thin film transistor TFT1 and a second thin film transistor TFT2, without being limited thereto.

The first thin film transistor TFT1 may include a first active layer ACT1, a first electrode E1a, a second electrode E1b, and a third electrode E1c. The first active layer ACT1 may be a first semiconductor layer, but embodiments of the disclosure are not limited thereto. For example, the first active layer ACT1 may be formed of an oxide semiconductor, amorphous silicon, polysilicon, or low temperature polysilicon (LTPS), but embodiments of the disclosure are not limited thereto. The first thin film transistor TFT1 may be implemented as a p-channel transistor or an n-channel thin film transistor, but embodiments of the disclosure are not limited thereto.

The first electrode E1a may be a gate electrode, the second electrode E1b may be a source electrode or a drain electrode, and the third electrode E1c may be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the disclosure are not limited thereto. However, embodiments of the disclosure are not limited thereto.

The second thin film transistor TFT2 may include a second active layer ACT2, a fourth electrode E2a, a fifth electrode E2b, and a sixth electrode E2c. The second active layer ACT2 may be a second semiconductor layer, but embodiments of the disclosure are not limited thereto. For example, the second active layer ACT2 may be formed of an oxide semiconductor, amorphous silicon, polysilicon, or low temperature polysilicon (LTPS), but embodiments of the disclosure are not limited thereto. The second thin film transistor TFT2 may be implemented as a p-channel transistor or an n-channel thin film transistor, but embodiments of the disclosure are not limited thereto.

For example, one of the first thin film transistor TFT1 and the second thin film transistor TFT2 may comprise an oxide semiconductor as an active layer. As another example, one of the first thin film transistor TFT1 and the second thin film transistor TFT2 may use low-temperature polysilicon as an active layer. As another example, the first thin film transistor TFT1 and the second thin film transistor TFT2 may configure an oxide semiconductor as an active layer. As another example, the first thin film transistor TFT1 and the second thin film transistor TFT2 may configure low-temperature polysilicon as an active layer. As another example, between the first thin film transistor TFT1 and the second thin film transistor TFT2, the driving transistor DT may configure an oxide semiconductor as an active layer, and the scan transistor ST may configure low-temperature polysilicon as an active layer. As another example, between the first thin film transistor TFT1 and the second thin film transistor TFT2, the driving transistor DT may configure low-temperature polysilicon as an active layer, and the scan transistor ST may configure an oxide semiconductor as an active layer. As another example, a transistor included in a gate driving circuit 130 of a gate in panel (GIP) type may configure an oxide semiconductor or low-temperature polysilicon as an active layer. As another example, all the transistors configured on the substrate 111 and transistors included in a gate driving circuit 130 of a gate in panel (GIP) type may configure an oxide semiconductor as an active layer. Embodiments of the disclosure are not limited thereto.

The fourth electrode E2a may be a gate electrode, the fifth electrode E2b may be a source electrode or a drain electrode, and the sixth electrode E2c may be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

The second active layer ACT2 of the second thin film transistor TFT2 may be positioned higher from the substrate 111 than the first active layer ACT1 of the first thin film transistor TFT1. Embodiments are not limited thereto. As an example, the second active layer ACT2 of the second thin film transistor TFT2 may be positioned lower from the substrate 111 than, at the same height from the substrate 111 as or on the same layer as the first active layer ACT1 of the first thin film transistor TFT1.

The first buffer layer 511 may be disposed under the first active layer ACT1 of the first thin film transistor TFT1, and a second buffer layer 514 may be disposed under the second active layer ACT2 of the second thin film transistor TFT2, without being limited thereto. For example, the first active layer ACT1 of the first thin film transistor TFT1 may be positioned on the first buffer layer 511, and the second active layer ACT2 of the second thin film transistor TFT2 may be positioned on the second buffer layer 514. The second buffer layer 514 may be positioned higher than the first buffer layer 511, without being limited thereto.

The storage capacitor Cst may be disposed in various metal layers in the display panel 110. For example, the storage capacitor Cst may include a first capacitor electrode CAPE1 and a second capacitor CAPE2.

The light emitting element unit may include a plurality of light emitting elements ED disposed on at least one planarization layer 521, 522, and 523. Each of the plurality of light emitting elements ED may include a pixel electrode PE, an intermediate layer EL, and a common electrode CE.

The encapsulation unit may include a first encapsulation layer 210 on the plurality of light emitting elements ED. The first encapsulation layer 210 may be a single layer or multiple layers, but embodiments of the disclosure are not limited thereto.

Hereinafter, a structure or a vertical structure of the display panel 110 according to exemplary embodiments of the disclosure is described in more detail with reference to FIG. 5.

Referring to FIG. 5, the first buffer layer 511 may be disposed on the substrate 111. The first buffer layer 511 may be a single layer or multiple layers, but embodiments of the disclosure are not limited thereto. When the first buffer layer 511 includes multiple layers, the first buffer layer 511 may include an lower buffer layer 511a and a upper buffer layer 511b.

The first active layer ACT1 of the first thin film transistor TFT1 may be disposed on the first buffer layer 511. The first active layer ACT1 may include a channel area in which a channel is formed, a source connection area on one side of the channel area, and a drain connection area on the other side of the channel area.

The first insulation layer 512 may be disposed on the first active layer ACT1 of the first thin film transistor TFT1. The first gate electrode E1a of the first thin film transistor TFT1 may be disposed on the first insulation layer 512. The second insulation layer 513 may be disposed on the first gate electrode E1a of the first thin film transistor TFT1. The first insulation layer 512 may be a gate insulation layer, but embodiments of the disclosure are not limited thereto. The second insulation layer 513 may be an interlayer insulation layer, but embodiments of the disclosure are not limited thereto.

The second buffer layer 514 may be disposed on the second insulation layer 513.

The second active layer ACT2 of the second thin film transistor TFT2 may be disposed on the second buffer layer 514. The second active layer ACT2 may include a channel area in which a channel is formed, a source connection area on one side of the channel area, and a drain connection area on the other side of the channel area.

The third insulation layer 515 may be disposed on the second active layer ACT2 of the second thin film transistor TFT2. The second gate electrode E2a of the second thin film transistor TFT2 may be disposed on the third insulation layer 515. The fourth insulation layer 516 may be disposed on the second gate electrode E2a of the second thin film transistor TFT2. The third insulation layer 515 may be a gate insulation layer, but embodiments of the disclosure are not limited thereto. The fourth insulation layer 516 may be an inter-layer insulation layer, but embodiments of the disclosure are not limited thereto.

The first source electrode E1b and the first drain electrode E1c of the first thin film transistor TFT1, and the second source electrode E2b and the second drain electrode E2c of the second thin film transistor TFT2 may be disposed on the fourth insulation layer 516, without being limited thereto.

The first source electrode E1b and the first drain electrode E1c of the first thin film transistor TFT1 may be connected to the source connection area and the drain connection area, respectively, of the first active layer ACT1 through holes of the fourth insulation layer 516, the third insulation layer 515, the second buffer layer 514, the second insulation layer 513, and the first insulation layer 512.

The second source electrode E2b and the second drain electrode E2c of the second thin film transistor TFT2 may be connected to the source connection area and the drain connection area, respectively, of the second active layer ACT2 through the holes of the fourth insulation layer 516 and the third insulation layer 515.

The first source electrode E1b and the first drain electrode E1c of the first thin film transistor TFT1, and the second source electrode E2b and the second drain electrode E2c of the second thin film transistor TFT2 may include a first metal and may be disposed in the first metal layer. Here, the first metal and the first metal layer may be referred to as a first source-drain metal and a first source-drain metal layer. Embodiments are not limited thereto. As an example, the first source electrode E1b and the first drain electrode E1c of the first thin film transistor TFT1, and the second source electrode E2b and the second drain electrode E2c of the second thin film transistor TFT2 may include different materials and/or may be disposed in different layers, without being limited thereto.

Referring to FIG. 5, e.g., the storage capacitor Cst may be formed by a first capacitor electrode CAPE1 and a second capacitor electrode CAPE2. In some cases, the storage capacitor Cst may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110.

For example, the first capacitor electrode CAPE1 may include the same first gate metal as the first gate electrode E1a of the first thin film transistor TFT1 on the first insulation layer 512 and may be disposed in the first gate metal layer, but embodiments of the disclosure are not limited thereto.

For example, the second capacitor electrode CAPE2 may be disposed on the second insulation layer 513, without being limited thereto.

The second source electrode E2b of the second thin film transistor TFT2 may be electrically connected to the second capacitor electrode CAPE2 through holes of the fourth insulation layer 516, the third insulation layer 515, and the second buffer layer 514.

For example, the first thin film transistor TFT1 may be the scan transistor ST of FIG. 2, and the second thin film transistor TFT2 may be the driving transistor DT of FIG. 2.

Referring to FIG. 5, as an example, the transistor unit may further include a first shield metal BSM1 disposed on the substrate 111. The first shield metal BSM1 may overlap the first active layer ACT1 of the first thin film transistor TFT1. The first shield metal BSM1 may be disposed under the first active layer ACT1 of the first thin film transistor TFT1. For example, the first shield metal BSM1 may be disposed between the substrate 111 and the first buffer layer 511, or may be disposed between the upper buffer layer 511a and the lower buffer layer 511a. As an example, the first shield metal BSM1 may be omitted depending on the design.

As an example, the transistor unit may further include a second shield metal BSM2 disposed on the substrate 111. The second shield metal BSM2 may overlap the second active layer ACT2 of the second thin film transistor TFT2. The second shield metal BSM2 may be disposed under the second active layer ACT2 of the second thin film transistor TFT2. As an example, the first shield metal BSM1 may be omitted depending on the design.

For example, the second shield metal BSM2 may be disposed in a metal layer between the second insulation layer 513 and the second buffer layer 514. The second shield metal BSM2 may be disposed in the same metal layer as the second capacitor CAPE2, but embodiments of the disclosure are not limited thereto.

As another example, the second shield metal BSM2 may be disposed in the same first gate metal layer as the first gate electrode E1a of the first thin film transistor TFT1, or disposed on any other layer below the second active layer ACT2.

At least one planarization layer may be disposed on the first thin film transistor TFT1 and the second thin film transistor TFT2. In the example of FIG. 5, three planarization layers 521, 522, and 523 are disposed on the first thin film transistor TFT1 and the second thin film transistor TFT2. In some cases, two planarization layers may be disposed on the first thin film transistor TFT1 and the second thin film transistor TFT2, but embodiments of the disclosure are not limited thereto.

Referring to FIG. 5, the first planarization layer 521 may be disposed on the first source electrode E1b and the first drain electrode E1c of the first thin film transistor TFT1, and the second source electrode E2b and the second drain electrode E2c of the second thin film transistor TFT2. For example, the first planarization layer 521 may be disposed on the first thin film transistor TFT1 and the second thin film transistor TFT2. For example, the first planarization layer 521 may be disposed while covering both the first thin film transistor TFT1 and the second thin film transistor TFT2.

Referring to FIG. 5, as an example, a first relay electrode RE1 may be disposed on the first planarization layer 521. The first relay electrode RE1 may electrically connect the second source electrode E2b of the second thin film transistor TFT2 and the pixel electrode PE.

The first relay electrode RE1 may be electrically connected to the second source electrode E2b of the second thin film transistor TFT2 through the hole of the first planarization layer 521. The second source electrode E2b of the second thin film transistor TFT2 may be electrically connected to the second capacitor electrode CAPE2 of the storage capacitor Cst.

The first relay electrode RE1 may be disposed in the second metal layer on the first planarization layer 521 and may include a second metal. The second metal and the second metal layer may be referred to as a second source-drain metal and a second source-drain metal layer.

The second planarization layer 523 may be disposed on the first relay electrode RE1. A second relay electrode RE2 may be disposed on the second planarization layer 523. As the second relay electrode RE2 is disposed, the lines included in the display panel 110 may be designed relatively more easily. The third planarization layer 523 may be disposed on the second relay electrode RE2. As an example, at least one of the first relay electrode RE1 and the second relay electrode RE2 may be omitted, depending on the design.

Referring to FIG. 5, the light emitting element unit may be disposed on the third planarization layer 523. The light emitting element ED may be formed on the third planarization layer 523. The light emitting element ED may include a pixel electrode PE, an intermediate layer EL, and a common electrode CE. The emission area of the light emitting element ED may be formed in an area in which the pixel electrode PE, the intermediate layer EL, and the common electrode CE overlap and contact each other.

The pixel electrode PE may be disposed on the third planarization layer 523. The pixel electrode PE may be electrically connected to the second relay electrode RE2 through the hole of the third planarization layer 523.

The black bank 531 may be disposed on the third planarization layer 523. A portion of the black bank 531 may be disposed on the pixel electrode PE.

The black bank 531 may reduce or minimize reflection of external light. The black bank 531 may include carbon black, black pigment, black dye, black resin, graphite powder, gravure ink, black spray, black enamel, etc.

The bank 532 may be disposed on the black bank 531. The opening of the bank 532 may expose a portion of the pixel electrode PE to form the emission area. For example, the opening of the bank 532 may overlap a portion of the pixel electrode PE. The bank 532 may be formed of a material including a black pigment, or an organic material such as a benzocyclobutene resin, a polyimide resin, an acrylic resin, or a photosensitive polymer, but embodiments of the disclosure are not limited thereto.

The spacer 533 may be disposed on the bank 532. The spacer 533 may reduce or prevent damage due to contact of the fine metal mask used in the process. The spacer 533 may be formed of a material including a black pigment, or an organic material such as a benzocyclobutene resin, a polyimide resin, an acrylic resin, or a photosensitive polymer, but embodiments of the disclosure are not limited thereto.

The intermediate layer EL of the light emitting element ED may be disposed on a portion of the pixel electrode PE and the spacer 533. The common electrode CE may be disposed on the intermediate layer EL.

Referring to FIG. 5, the encapsulation unit may be disposed on the light emitting element unit and may be positioned on the common electrode CE. The encapsulation unit may include the first encapsulation layer 210 formed on the common electrode CE.

The first encapsulation layer 210 may reduce or prevent moisture or oxygen from penetrating into the light emitting element ED. For example, the first encapsulation layer 210 may reduce or prevent moisture or oxygen from penetrating into the organic material included in the intermediate layer EL of the light emitting element ED. The first encapsulation layer 210 may be formed of a single layer or multiple layers, but embodiments of the disclosure are not limited thereto.

Referring to FIG. 5, e.g., the first encapsulation layer 210 may include a first inorganic encapsulation layer 211, a first organic encapsulation layer 212, and a second inorganic encapsulation layer 213, but embodiments of the disclosure are not limited thereto. For example, the first inorganic encapsulation layer 211 and the second inorganic encapsulation layer 213 may include an inorganic layer, and the first organic encapsulation layer 212 may include an organic layer, but embodiments of the disclosure are not limited thereto.

The display panel 110 according to exemplary embodiments of the disclosure may include a touch sensor. In this case, the display panel 110 according to exemplary embodiments of the disclosure may include a touch sensor layer 220 formed on the first encapsulation layer 210. The touch sensor layer 220 may be a touch unit.

Referring to FIG. 5, the touch sensor layer 220 may include a plurality of touch electrodes TE, and may include a first touch metal TM1 and a second touch metal TM2 to form the plurality of touch electrodes TE. In exemplary embodiments of the disclosure, the layer on which the second touch metal TM2 is disposed may be referred to as a sensor metal layer, and the layer on which the first touch metal TM1 is disposed may be referred to as a bridge metal layer.

The touch sensor layer 220 may further include insulation layers, such as a touch buffer layer 221 on the first encapsulation layer 210, a touch interlayer insulation layer 222 on the touch buffer layer 221, etc. Here, the touch buffer layer 221 may be omitted.

The first touch metal TM1 may be disposed between the touch buffer layer 221 and the touch interlayer insulation layer 222. The second touch metal TM2 may be disposed between the touch interlayer insulation layer 222 and the color filter buffer layer 251.

Each of the plurality of touch electrodes TE may be formed of the second touch metal TM2. Each of the plurality of touch electrodes TE may be a mesh type electrode having a plurality of openings, but embodiments of the disclosure are not limited thereto. As an example, each of the plurality of touch electrodes TE may be a block type electrode having no opening.

The plurality of touch electrodes TE may include a first touch electrode TE1 and a second touch electrode TE2. The second touch metal TM2 included in the first touch electrode TE1 may be electrically connected through the first touch metal TM1. For example, the second touch metals TM2 spaced apart from each other may be electrically connected by the first touch metal TM1 to constitute one first touch electrode TE1.

The first touch metals TM1 may be disposed on the buffer layer 221. The touch interlayer insulation layer 222 may be disposed on the first touch metals TM1. The second touch metal TM2 may be disposed on the touch interlayer insulation layer 222. Some of the second touch metals TM2 may be connected to the corresponding first touch metal TM1 through a hole in the insulation layer 222.

Referring to FIG. 5, the first touch metals TM1 and the second touch metals TM2 may be disposed not to overlap the light emitting element ED. The first touch metals TM1 and the second touch metals TM2 may overlap the bank 532. Embodiments are not limited thereto. As an example, the first touch metals TM1 and the second touch metals TM2 may be disposed to overlap the light emitting element ED. As an example, each of the plurality of touch electrodes TE may be a transparent electrode or an opaque electrode, without being limited thereto.

The plurality of second touch metals TM2 may constitute one touch electrode TE. The plurality of second touch metals TM2 may be disposed in a mesh form and electrically connected to each other. A portion of the second touch metal TM2 and another portion of the second touch metal TM2 may be electrically connected through the first touch metal TM1 to constitute one touch electrode TE.

As an example, the color filter layer 250 may be disposed on the touch sensor layer 220.

The color filter layer 250 may include a color filter buffer layer 251, a black matrix 252, a plurality of color filters 253, and an overcoat layer 254.

The color filter buffer layer 251 may be disposed on the second touch metal TM2.

The color filter buffer layer 251 may be an inorganic insulation layer. However, the color filter buffer layer 251 may be an organic insulation layer.

The black matrix 252 may be disposed on the color filter buffer layer 251. As an example, the black matrix 252 may be omitted depending on the design.

The black matrix 252 may be disposed to overlap the bank 532. Further, the black matrix 252 may be disposed to overlap the black bank 531.

Referring to FIG. 5, the emission area EA may be an area in which the pixel electrode PE, the intermediate layer EL, and the common electrode CE overlap. Further, the emission area EA may be an area in which the light emitting element ED is disposed. The emission area EA may be an area in which the emission layer EML included in the intermediate layer EL is disposed.

The black bank 531 may include a plurality of first opening areas OA1, and a plurality of first opening areas OA1 of the black bank 531 may overlap the emission area EA. As an example, the first opening area OA1 of the black bank 531 may be wider than the emission area EA. Further, as an example, while the first opening area OA1 of the black bank 531 is wider than the emission area EA, the emission area EA may be positioned to be included in the first opening area OA1 of the black bank 531. Assuming that the emission area EA and the first opening area OA1 of the black bank 531 have a circular shape, the emission area EA may be positioned inside the first opening area OA1 of the black bank 531. Embodiments are not limited thereto. As an example, the first opening area OA1 of the black bank 531 may be equal to or wider than the emission area EA. As an example, the emission area EA may be positioned to correspond to the first opening area OA1 of the black bank 531. As an example, the emission area EA and the first opening area OA1 of the black bank 531 have various shapes other than the circular shape, such as a rectangle shape, an oval shape, a polygonal shape, etc.

The black matrix 252 may include a plurality of second opening areas OA2. The plurality of second opening areas OA2 of the black matrix 252 may overlap the plurality of first opening areas OA1 of the black bank 531. The area of the second opening area OA2 may be larger than the area of the first opening area OA1. When it is assumed that the second opening area OA2 and the first opening area OA1 have circular shapes, the first opening area OA1 may be positioned inside the second opening area OA2.

The plurality of second opening areas OA2 of the black matrix 252 may overlap the emission area EA. The area of the second opening area OA2 may be larger than the area of the emission area EA. Assuming that the second opening area OA2 and the emission area EA have circular shapes, the emission area EA may be positioned inside the second opening area OA2.

Assuming that the emission area EA, the first opening area OA1, and the second opening area OA2 have a circular shape, the emission area EA may be positioned inside the first opening area OA1 and the second opening area OA2, and the first opening area OA1 may be positioned inside the second opening area OA2.

Since the second opening area OA2 is wider than the emission area EA, light emitted from the emission area EA may be emitted not only from the front surface but also from the side surface. Since light is emitted not only from the front surface but also from the side surface, light emitted from the emission area EA may be emitted with a predetermined viewing angle.

The viewing angle may be designed to differ according to the position difference between the emission area EA and the second opening area OA2. On the other hand, when the second opening area OA2 is designed to be larger than the emission area EA, external light may enter the display panel 110 through the second opening area OA2 that does not overlap the emission area EA. When external light enters the display panel 110, it may be reflected to the user. When the external light is reflected to the user, the image displayed on the display panel 110 may not be easily visible. In order to reduce or prevent reflection of external light, the first opening area OA1 may be designed to be smaller than the second opening area OA2. Referring to FIG. 5, since the first opening area OA1 is designed to be smaller than the second opening area OA2, external light entering through the second opening area OA2 may reach the black bank 531. External light reaching the black bank 531 may not be reflected to the user.

A plurality of color filters 253 may be disposed on the color filter buffer layer 251. Some of the plurality of color filters 253 may be disposed to overlap the black matrix 252.

The plurality of color filters 253 may change the color of light passing through the plurality of color filters 253.

The plurality of color filters 253 may include a red color filter, a green color filter, and a blue color filter. However, the disclosure is not limited thereto, and the plurality of color filters 253 may include color filters of different colors.

Referring to FIG. 5, the plurality of color filters 253 may include a first color filter 253a and a second color filter 253b.

The first color filter 253a may be disposed to overlap the light emitting element ED.

The overcoat layer 254 may be disposed on the plurality of color filters 253. The overcoat layer 254 may include an organic insulating material. As the color filter layer 250 includes the overcoat layer 254, the upper surface of the color filter layer 250 may be planarized.

The second organic encapsulation layer 260 may be disposed on the overcoat layer 254. The second organic encapsulation layer 260 may include an organic insulating material.

An adhesive layer 540 may be disposed on the second organic encapsulation layer 260. The adhesive layer 540 may reduce reflectance of external light. The adhesive layer 540 may decrease transmittance of external light in a specific wavelength band.

A cover window 550 may be disposed on the adhesive layer 540. The cover window 550 may be disposed on an uppermost portion of the display panel 110, and the cover window 550 may protect the display panel 110 from an external impact.

A cross-sectional view of the display area DA of the display panel 110 has been described. Hereinafter, the non-display area NDA of the display panel 110 is also described.

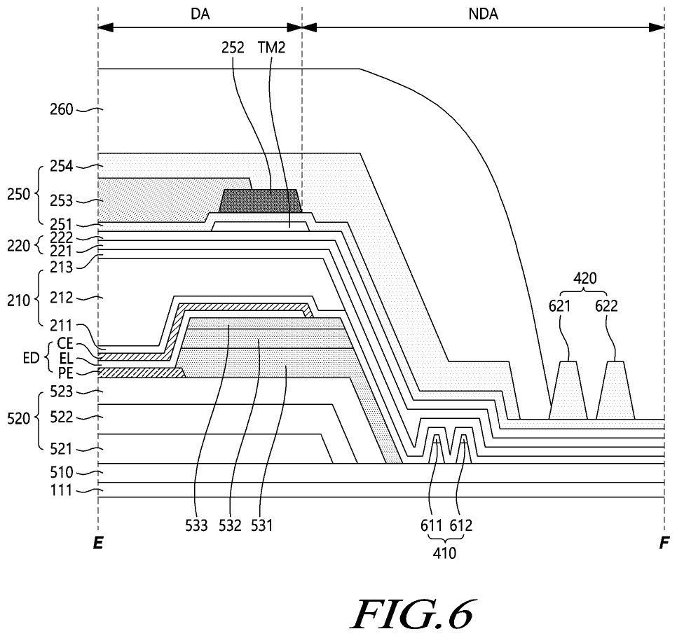

FIGS. 6 to 13 are cross-sectional views illustrating an E-F area of a display panel 110 according to exemplary embodiments of the disclosure.

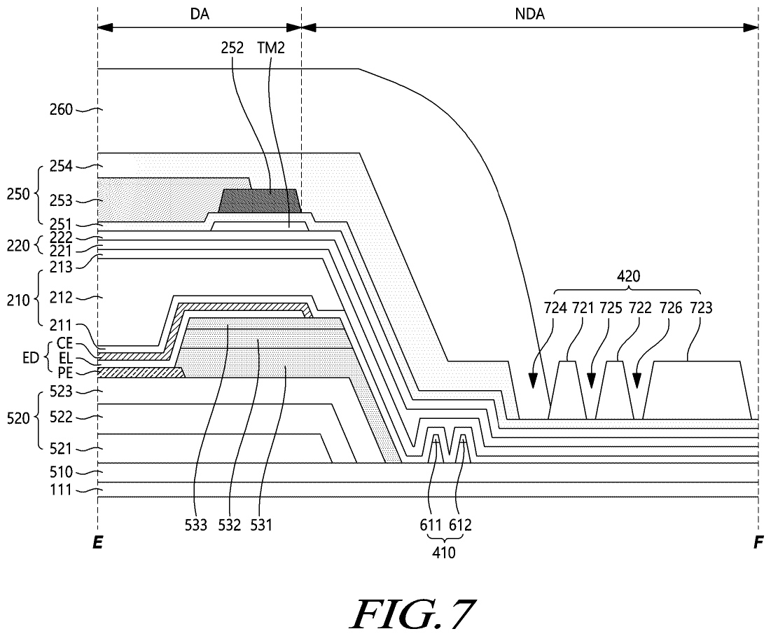

FIGS. 6 and 7 are cross-sectional views of a display panel, illustrating an outer dam portion including a single material according to exemplary embodiments of the disclosure.

Among the components illustrated in FIG. 6, descriptions of the same components as those illustrated in FIG. 5 may be omitted or briefly given.

The substrate 111 may include a display area DA and a non-display area NDA outside the display area DA. The display area DA may be an area in which the light emitting element ED is disposed. The boundary between the display area DA and the non-display area NDA may be a position of an end of the black matrix 252, but is not limited thereto. As an example, the boundary between the display area DA and the non-display area NDA may be a position of an end of the black matrix toward the non-display area NDA, without being limited thereto. As an example, the boundary between the display area DA and the non-display area NDA may be a position of an end of the outermost color filter toward the non-display area NDA, without being limited thereto.

The insulation layers 510 may be disposed on the substrate 111. The insulation layers 510 may be substantially the same as the insulation layers 510 shown in FIG. 5.

The planarization layers 520 may be disposed on the insulation layers 510. The planarization layers 520 may be substantially the same as the planarization layers 520 shown in FIG. 5. The first planarization layer 521 may be disposed on the substrate. The second planarization layer 522 may be disposed on the first planarization layer 521, and may extend to an outer area of the first planarization layer 521 to be disposed in contact with the substrate. The second planarization layer 522 may include an inclined surface having an inclination at the outside of the first planarization layer 521. The third planarization layer 523 may be disposed on the second planarization layer 522, and may extend to an outer area of the second planarization layer 522 to be disposed in contact with the substrate. The third planarization layer 523 may include an inclined surface having an inclination at the outside of the second planarization layer 522. Embodiments are not limited thereto. As an example, the second planarization layer 522 may be aligned with the first planarization layer 521, and/or the third planarization layer 523 may be aligned with the second planarization layer 522, without being limited thereto. As an example, the first planarization layer 521 and/or the second planarization layer 522 may not be in contact with the substrate, without being limited thereto.

The black bank 531 may be disposed on the third planarization layer 523. A portion of the black bank 531 may be disposed on the inclined surface of the third planarization layer 523. The bank 532 may be disposed on the black bank 531. The spacer 533 may be disposed on the bank 532. As an example, the bank 532 and/or the spacer 533 may be disposed on, or not disposed on the inclined surface of the black bank 531. At least one of the bank 532 and the black bank 531 may define an emission area of the light emitting element.

The pixel electrode PE may be disposed on the third planarization layer 523. The intermediate layer EL may be disposed on the pixel electrode PE, and the common electrode CE may be disposed on the intermediate layer EL. The intermediate layer EL may be disposed in contact with the pixel electrode PE. A portion of the intermediate layer EL may be disposed to overlap the spacer 533, the bank 532, and the black bank 531. As an example, the intermediate layer EL may be disposed to overlap the pixel electrode PE, and may extend to an upper portion of the spacer 533. The common electrode CE may be disposed on the intermediate layer EL, and the common electrode CE may be disposed to overlap the spacer 533. As an example, the common electrode may cover the end of the intermediate layer EL on the spacer 533, without being limited thereto. As an example, the common electrode may be in contact with the spacer 533, without being limited thereto.

The inner dam portion 410 may be disposed outside the third planarization layer 523. The inner dam portion 410 may include one or more materials. For example, the inner dam portion 410 may include the same material as the material included in the bank 532. Further, the inner dam portion 410 may include the same material as the material included in the spacer 533. Further, the inner dam portion 410 may include the same material as the material included in the planarization layers 520. Embodiments are not limited thereto. As an example, the inner dam portion 410 may include a material different from the bank 532, the spacer 533 and the planarization layers 520. As an example, the inner dam portion 410 may include the same material as all of the bank 532, the spacer 533 and the planarization layers 520. As an example, the inner dam portion 410 may include an additional material in addition to the material of the bank 532, the spacer 533 and/or the planarization layers 520.

The first inorganic encapsulation layer 211 may be disposed on the common electrode CE, and the first inorganic encapsulation layer 211 may extend to an upper portion of the inner dam portion 410. Further, the first inorganic encapsulation layer 211 may be disposed to extend to a lower portion of the outer dam portion 420. As an example, the first inorganic encapsulation layer 211 may be disposed to extend to outside of the inner dam portion 410. As an example, the first inorganic encapsulation layer 211 may be disposed to extend between two inner dam portions 410.

The first organic encapsulation layer 212 may be disposed on the first inorganic encapsulation layer 211. As an example, the first organic encapsulation layer 212 may not be disposed on the inclined surface of the first inorganic encapsulation layer 211, without being limited thereto. As an example, the first organic encapsulation layer 212 may not extend to the inner dam portion 410.

The second inorganic encapsulation layer 213 is disposed on the first organic encapsulation layer 212 and may extend to a side surface of the first organic encapsulation layer 212. The second inorganic encapsulation layer 213 may be disposed in contact with the first inorganic encapsulation layer 211.

The second inorganic encapsulation layer 213 may extend to an upper portion of the inner dam portion 410. Further, the second inorganic encapsulation layer 213 may extend to a lower portion of the outer dam portion 420.

At least one of the plurality of encapsulation layers 210 and 260 may extend to the upper portion of the inner dam portion 410 and the lower portion of the outer dam portion 420.

The plurality of encapsulation layers 210 and 260 may include a first organic encapsulation layer 212 and a second organic layer disposed on the first organic encapsulation layer 212.

The plurality of encapsulation layers 210 and 260 may further include a first inorganic encapsulation layer 211 disposed under the first organic encapsulation layer 212, and a second inorganic encapsulation layer 213 disposed between the first organic encapsulation layer 212 and the second organic encapsulation layer 260, and at least one of the first inorganic encapsulation layer 211 and the second inorganic encapsulation layer 213 may extend to an upper portion of the inner dam portion 410 and a lower portion of the outer dam portion 420.

The inner dam portion 410 may be disposed on the substrate 111, may be disposed outside the first organic encapsulation layer 212, and may be disposed under at least one of the first inorganic encapsulation layer 211 and the second inorganic encapsulation layer 213.

The touch sensor layer 220 may be disposed on the second inorganic encapsulation layer 213. The touch buffer layer 221 may be disposed on the second inorganic encapsulation layer 213. The touch interlayer insulation layer 222 may be disposed on the touch buffer layer 221. The second touch metal TM2 may be disposed on the touch interlayer insulation layer 222. The second touch metal TM2 may be disposed to overlap the black bank 531, without being limited thereto.

The touch buffer layer 221 and the touch interlayer insulation layer 222 may be disposed to extend to an upper portion of the inner dam portion 410. Further, the touch buffer layer 221 and the touch interlayer insulation layer 222 may be disposed to extend to a lower portion of the outer dam portion 420.

The color filter layer 250 may be disposed on the touch sensor layer 220.

The color filter buffer layer 251 may be disposed on the touch interlayer insulation layer 222. The color filter buffer layer 251 may be disposed to extend to an upper portion of the inner dam portion 410. Further, the color filter buffer layer 251 may be disposed to extend to a lower portion of the outer dam portion 420.

The black matrix 252 may be disposed to overlap the black bank 531.

A plurality of color filters 253 may be disposed on the color filter buffer layer 251. At least some of the plurality of color filters 253 may be disposed to overlap the light emitting element ED. As an example, the plurality of color filters 253 may be disposed to extend to an upper portion of the black matrix 252, and the plurality of color filters 253 may be disposed on the black matrix 252 to overlap the black matrix 252, without being limited thereto. As an example, the plurality of color filters 253 may be in contact with the black matrix 252. As an example, the color filters 253 may be disposed to not extend to an upper portion of the black matrix 252, or may be disposed to cover the upper portion of the black matrix 252, without being limited thereto.

Some of the plurality of color filters 253 may be disposed to overlap the black matrix 252.

The overcoat layer 254 may be disposed on the plurality of color filters 253 and the black matrix 252. The overcoat layer 254 may be disposed to extend from the display area DA to the non-display area NDA. Referring to FIG. 6, an overcoat layer 254 may be disposed on the inclined surface of the color filter buffer layer 251.

The second organic encapsulation layer 260 may be disposed on the overcoat layer 254 and may extend to an upper portion of the inner dam portion 410.

The outer dam portion 420 may reduce or prevent the second organic encapsulation layer 260 from departing from a specific area. As an example, the outer dam portion 420 may reduce or prevent the second organic encapsulation layer 260 from flowing over a specific area of the outer dam portion 420.

As an example, the outer dam portion 420 may be disposed on the color filter buffer layer 251, without being limited thereto.

The outer dam portion 420 may be disposed in the non-display area NDA.

The outer dam portion 420 may be disposed outside the overcoat layer 254. The outer dam portion 420 may be disposed to be spaced apart from the overcoat layer 254.

The outer dam portion 420 may be disposed outside the second organic encapsulation layer 260. As an example, the outer dam portion 420 may include an insulating material included in the overcoat layer 254, without being limited thereto.

The outer dam portion 420 may include at least one of organic insulating materials such as an acrylate resin, an epoxy resin, a phenolic resin, a polyamide resin, a polyimide resin, a polyester resin, a polyphenylene sulfide resin, or a benzocyclobutene (BCB).

The outer dam portion 420 may include one or more dams. Referring to FIG. 6, the outer dam portion 420 may include a first dam 621 and a second dam 622. As an example, the height of the upper surface of the first dam 621 may be the same as the height of the upper surface of the overcoat layer 254 adjacent to the first dam 621. As an example, the height of the upper surface of the first dam 621 may be the same as the height of the upper surface of the second dam 622. As an example, at least one of the height of the upper surface of the first dam 621, the height of the upper surface of the second dam 622 and the height of the upper surface of the overcoat layer 254 adjacent to the first dam 621 may be different, without being limited thereto.

After the overcoat layer 254 is deposited on the entire surface, a portion of the overcoat layer 254 is etched, so that an outer dam portion 420 may be formed. However, as an example, after the overcoat layer 254 is disposed, the outer dam portion 420 may be separately disposed.

A plurality of insulation layers may be disposed under the outer dam portion 420.

The outer dam portion 420 may be disposed further outside than the inner dam portion 410. The outer dam portion 420 may be disposed farther from the first organic encapsulation layer 212 than the inner dam portion 410.

The inner dam portion 410 may include a material included in the bank 532, and the outer dam portion 420 may include a material included in the overcoat layer 254, without being limited thereto.

The outer dam portion 420 may be disposed in contact with the second organic encapsulation layer 260. Alternatively, the outer dam portion 420 may be disposed outside the second organic encapsulation layer 260. Alternatively, the outer dam portion 420 may be covered by the second organic encapsulation layer 260.

Referring to FIG. 7, after the overcoat layer 254 is deposited on the entire surface, a portion of the overcoat layer 254 is etched and removed, and thus an outer dam portion 420 may be disposed. For example, as the first hole portion 724, the second hole portion 725, and the third hole portion 726 are etched and removed, the color filter buffer layer covered by the overcoat layer 254 may be exposed.

As the first hole portion 724, the second hole portion 725, and the third hole portion 726 are etched and removed from the overcoat layer 254, the first dam 721, the second dam 722, and the third dam 723 of the outer dam portion 420 may be formed.

The first dam 721 of the outer dam portion 420 may be disposed to be spaced apart from the overcoat layer 254.

The second dam 722 of the outer dam portion 420 may be disposed outside the second hole portion 725 of the outer dam portion 420.

The third dam 723 of the outer dam portion 420 may be disposed outside the third hole portion 726 of the outer dam portion 420. As an example, the third dam 723 may have a width larger than those of the first dam 721 and the second dam 722, without being limited thereto. Referring to FIG. 7, the width is the length in the horizontal direction. The length of the third dam 723 in the horizontal direction may be larger than the length of the first dam 721. Embodiments are not limited thereto. As an example, the third dam 723 may have a width equal to or smaller than those of the first dam 721 and the second dam 722. As an example, the first dam 721 may have a width larger than, equal to or smaller than those of the second dam 722.

The shape of the outer dam portion 420 illustrated in FIG. 6 may be defined as an embossed shape, and the shape of the outer dam portion 420 illustrated in FIG. 7 may be defined as an engraved shape.

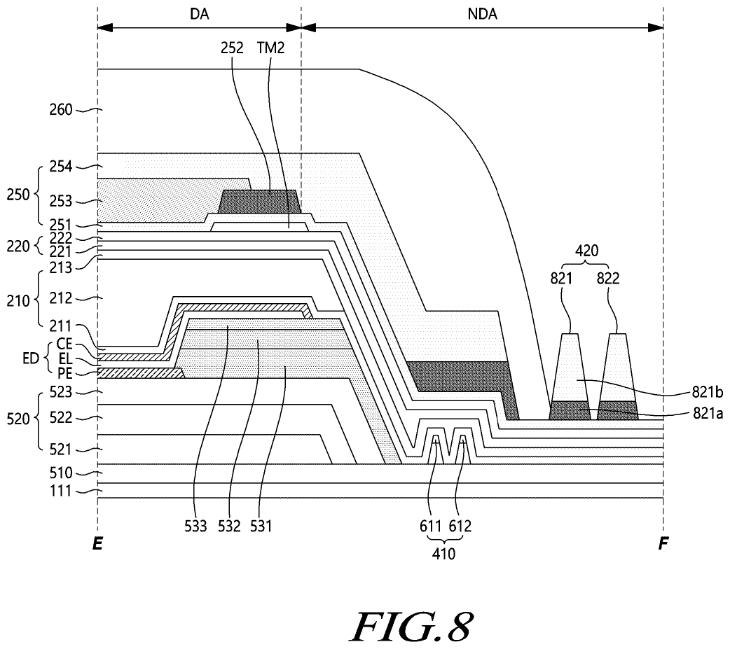

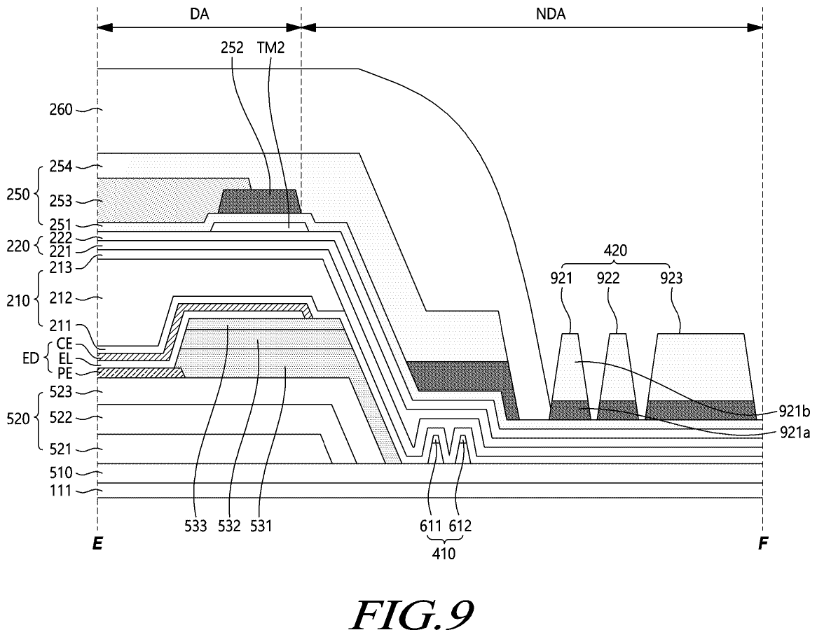

FIGS. 8 and 9 are cross-sectional views of a display panel illustrating an outer dam portion 420 including two materials according to exemplary embodiments of the disclosure.

Referring to FIGS. 6 and 8, unlike the outer dam portion 420 illustrated in FIG. 6, the outer dam portion 420 illustrated in FIG. 8 may include two materials. Among the descriptions of FIG. 8, contents overlapping the description of FIG. 6 may be omitted or briefly given.

A black matrix 252 or a color filter 253 may be further disposed at a position where the inner dam portion 410 overlaps the overcoat layer 254. For example, the black matrix 252 (or color filter 253) may be disposed at a position where the color filter buffer layer 251 overlaps the inner dam 410, and may be disposed up to the outer area of the inner dam 410. Thereafter, the black matrix 252 (or the color filter 253) may be covered by the overcoat layer 254. As an example, the black matrix 252 (or the color filter 253) may be disposed under the overcoat layer 254. Subsequently, the black matrix 252 (or the color filter 253) and a portion of the overcoat layer 254 may be etched and removed. Accordingly, the outer dam portion 420 may be formed. However, after disposing the black matrix 252 (or the color filter 253) and the overcoat layer 254, the outer dam portion 420 may be separately disposed.

Referring to FIG. 8, the outer dam portion 420 may include a first portion 821a and a second portion 821b disposed on the first portion 821a.

The first portion 821a may include the same material as the material included in the black matrix 252 or the color filter 253.

The second portion 821b may include the same material as the material included in the overcoat layer 254.

The outer dam portion 420 of FIG. 8 is shown in an embossed shape, and the outer dam portion 420 of FIG. 9 is shown in an engraved shape.

Referring to FIGS. 7 and 9, unlike the outer dam portion 420 illustrated in FIG. 7, the outer dam portion 420 illustrated in FIG. 9 may include two materials. Among the descriptions of FIG. 9, contents overlapping the description of FIG. 7 may be omitted or briefly given.

The outer dam portion 420 may include a first dam 921, a second dam 922, and a third dam 923.

The first dam 921 may be disposed to be spaced apart from the overcoat layer 254.

The second dam 922 may be disposed to be spaced apart from the first dam 921.

The third dam 923 be disposed to be spaced apart from the second dam 922, and may have a width larger than that of the first dam 921.

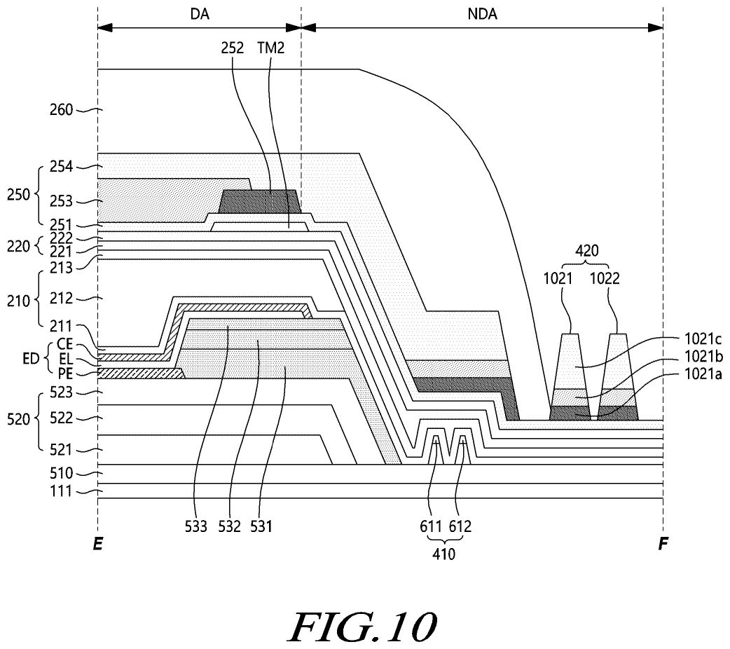

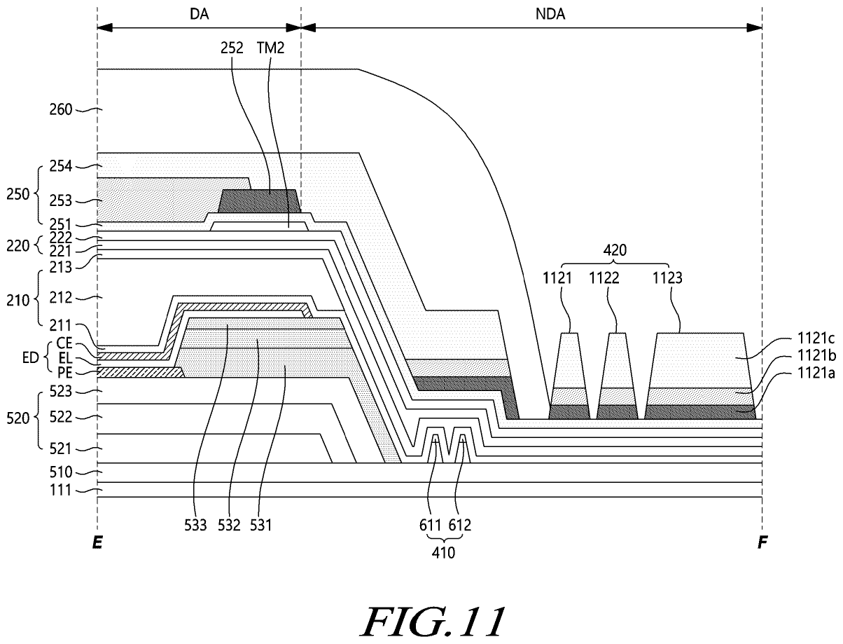

FIGS. 10 and 11 are cross-sectional views of a display panel 110 illustrating an outer dam portion 420 including three materials according to exemplary embodiments of the disclosure.

Referring to FIGS. 8 and 10, unlike the outer dam portion 420 illustrated in FIG. 8, the outer dam portion 420 illustrated in FIG. 10 may include three materials. Among the descriptions of FIG. 10, contents overlapping the description of FIG. 8 may be omitted or briefly given.

Referring to FIG. 10, a black matrix 252 and a color filter 253 may be further disposed at a position where the inner dam portion 410 overlaps the overcoat layer 254. For example, the black matrix 252 may be disposed at a position where the color filter buffer layer 251 overlaps the inner dam 410, and may be disposed up to the outer area of the inner dam 410. The color filter 253 may be disposed on the black matrix 252. The color filter 253 may be disposed at a position where the color filter buffer layer 251 overlaps the inner dam portion 410, and may be disposed up to an outer area of the inner dam portion 410.

Thereafter, the color filter 253 may be covered by the overcoat layer 254. As an example, the color filter 253 may be disposed on the black matrix 252, and the overcoat layer 254 may be disposed on the color filter 253. Subsequently, portions of the black matrix 252, the color filter 253, and the overcoat layer 254 may be etched and removed. Accordingly, the outer dam portion 420 may be formed. However, after disposing the black matrix 252, the color filter 253, and the overcoat layer 254, the outer dam portion 420 may be separately disposed.

The outer dam portion 420 may include the same material as the material included in the overcoat layer 254. Further, between the inner dam portion 410 and the outer dam portion 420, the outer dam portion 420 may further include a material included in at least one of the black matrix 252 and the color filter 253.

The outer dam portion 420 may include a first portion 1021a, a second portion 1021b, and a third portion 1021c.

The first portion 1021a may include the same material as the material included in the black matrix 252.

The second portion 1021b is disposed on the first portion 1021a of the outer dam portion 420 and may include the same material as the material included in the color filter 253.

The third portion 1021c is disposed on the second portion 1021b of the outer dam portion 420, and may include the same material as the material included in the overcoat layer 254.

Referring to FIG. 11, the outer dam portion 420 may include a first dam 1121, a second dam 1122, and a third dam 1123. As an example, the width of the third dam 1123 may be larger than the widths of the first dam 1121 and the second dam 1122, without being limited thereto.

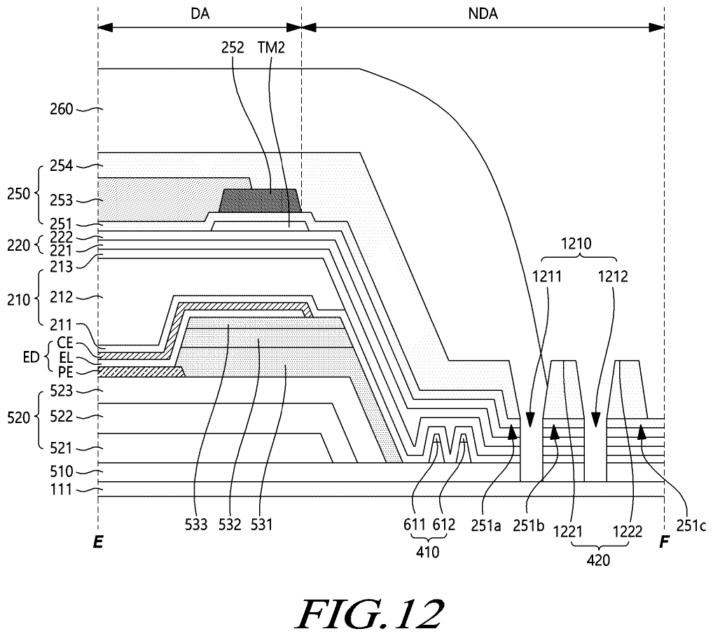

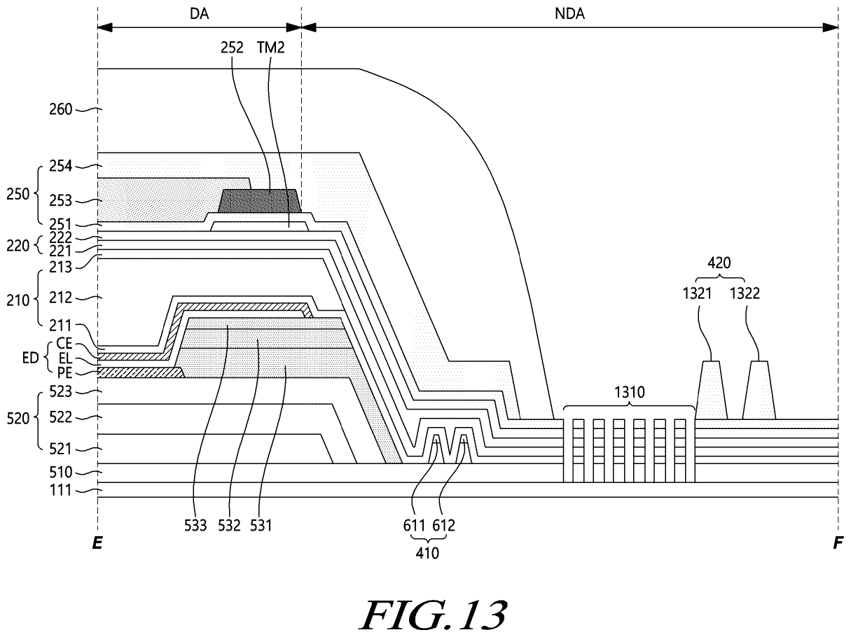

FIGS. 12 and 13 are cross-sectional views illustrating a display panel including a recess according to exemplary embodiments of the disclosure.

Referring to FIG. 6, a plurality of insulation layers are disposed between the overcoat layer 254 and the first dam 1221. When the plurality of insulation layers disposed between the first dam 1221 and the overcoat layer 254 illustrated in FIG. 6 are etched and removed, a first recess 1211 illustrated in FIG. 12 may be formed. As an example, the insulation layers may include recesses 1211 and 1212, without being limited thereto. Referring to FIG. 6, a structure for reducing or preventing overflow of the second organic encapsulation layer 260 is an outer dam portion 420. Referring to FIG. 12, structures for reducing or preventing overflow of the second organic encapsulation layer 260 are an outer dam portion 420 and holes. As an example, as the recesses 1211 and 1212 are disposed, overflow of the second organic encapsulation layer 260 may be more easily reduced or prevented.

Referring to FIG. 12, the first recess 1211 may be disposed inside the first dam 1221 of the outer dam portion 420. The first recess 1211 may be disposed outside the inner dam portion 410. The first recess 1211 may be disposed further outside than the overcoat layer 254.

Referring to FIG. 12, the second recess 1212 may be disposed outside the first dam 1221 of the outer dam portion 420.

As the insulation layers disposed in the area between the overcoat layer 254 and the first dam 1221 are etched and removed, a first recess 1211 may be formed.

Further, as the insulation layers disposed in the area between the first dam 1221 and the second dam 1222 are etched and removed, a second recess 1212 may be formed.

As the first dam 1221 is disposed adjacent to the first recess 1211 and the second recess 1212, the second organic encapsulation layer 260 may also be disposed in the first recess 1211 and/or the second recess 1212. As an example, as the first recess 1211 and the second recess 1212 are disposed adjacent to the first dam 1221, the function of the outer dam portion 420 for reducing or preventing overflow of the second organic encapsulation layer 260 may be further enhanced.

Referring to FIG. 12, in order to form the first recess 1211, the color filter buffer layer 251, the touch interlayer insulation layer 222, the touch buffer layer 221, the second inorganic encapsulation layer 213, and the first inorganic encapsulation layer 211 may be etched and removed. Accordingly, the substrate 111 may be exposed in the area where the first recess 1211 is formed. The second organic encapsulation layer 260 may flow into the first recess, and accordingly, the second organic encapsulation layer 260 may be disposed in contact with the substrate 111.

However, even if only the color filter buffer layer 251 is removed, the first recess 1211 may be formed. When a portion of the color filter buffer layer 251 is removed, the color filter buffer layer 251 may include a first portion 251a, a second portion 251b, and a third portion 251c.

Further, it may further include a first recess 1211 disposed in an area between the inner dam portion 410 and the outer dam portion 420 and having a shape in which the first inorganic encapsulation layer 211 and the second inorganic encapsulation layer 213 are dug.

Referring to FIG. 13, as an example, a plurality of recesses 1310 may be disposed between the overcoat layer 254 and the outer dam portion 420.

Referring to FIG. 13, seven recesses are disposed between the overcoat layer 254 and the outer dam portion 420. As a portion of the insulation layer disposed between the overcoat layer 254 and the outer dam portion 420 is etched, a plurality of recesses 1310 may be disposed.

As a plurality of recesses shaped to have been dug are disposed, some of the insulation layers may be disposed in the form of a dam. Referring to FIG. 13, some of the insulation layers are illustrated in the form of six dams. The plurality of recesses 1310 may have a hole shape. As an example, one or more recesses may be disposed between the overcoat layer 254 and the outer dam portion 420. As an example, the recess may expose any of the color filter buffer layer 251, the touch interlayer insulation layer 222, the touch buffer layer 221, the second inorganic encapsulation layer 213, the first inorganic encapsulation layer 211, and the substrate 111. As an examiner, there is no dam portion between the one or more recesses. As an example, an end of the outmost recess among the one or more recesses toward the outer dam portion 420 may be aligned with an end of the outer dam portion 420, without being limited thereto.

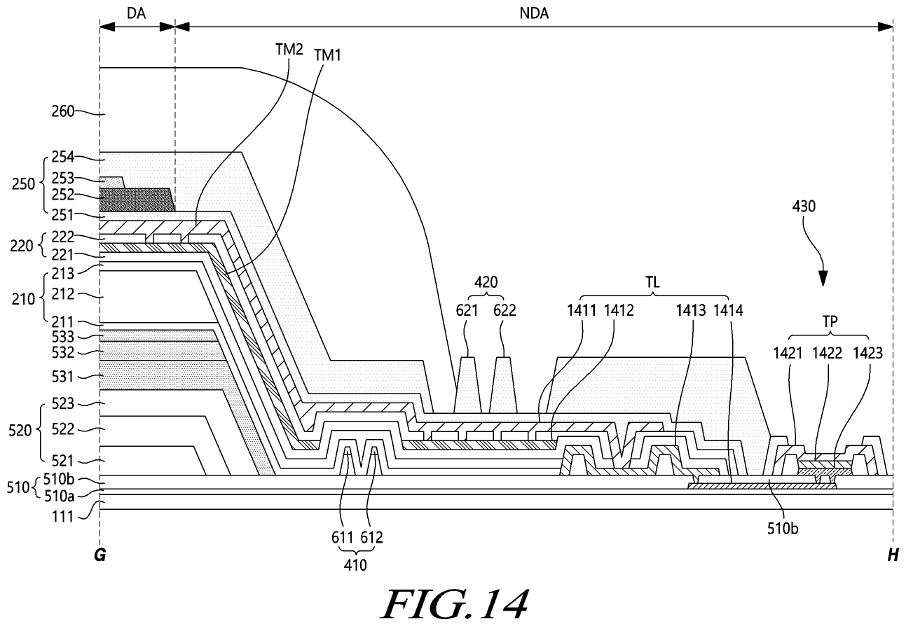

FIG. 14 is a cross-sectional view illustrating an E-F area of a display panel 110 as illustrated in FIG. 4.

Referring to FIG. 14, unlike the configuration illustrated in FIG. 6, a touch line TL and a touch pad TP are added. The description focuses primarily on the touch line TL and a touch pad TP. The same or similar configuration as the configuration illustrated in FIG. 6 may be excluded from the description of FIG. 14.

The touch sensor layer 220 may be disposed between the second inorganic encapsulation layer 213 and the black matrix 252.

The touch sensor layer 220 may include a touch buffer layer 221, a first touch metal TM1, a touch interlayer insulation layer 222, and a second touch metal TM2.

The touch buffer layer 221 may be disposed on the second inorganic encapsulation layer 213.

The touch buffer layer 221 may extend to pass through the upper portion of the inner dam portion 410 and the lower portion of the outer dam portion 420.

The first planarization layer 521 may be patterned and disposed in an area further outside than the outer dam portion 420. Referring to FIG. 14, the four patterned first planarization layers 521 may be disposed to be spaced apart from each other. A second source drain metal 1413 may be disposed on upper surfaces of the two first planarization layers 521. The touch buffer layer 221 may be disposed to pass through the upper surfaces of the two patterned first planarization layers 521. The touch buffer layer 221 may be disposed on the second source drain metal 1413 disposed on the first planarization layer 521.

The first touch metals TM1 may be disposed on the buffer layer 221. The layer on which the first touch metal TM1 is disposed may be referred to as a first touch metal layer.

The first touch metal TM1 may be disposed to extend from an area overlapping the first organic encapsulation layer 212 to an area adjacent to the inner dam portion 410. Referring to FIG. 14, the first touch metal TM1 is disposed in an inclined area formed outside the first organic encapsulation layer 212 and is disconnected at the upper portion of the inner dam portion 410. When the first touch metal TM1 is disposed on the upper portion of the inner dam portion 410, a crack may occur in the first touch metal TM1 due to an outer inclination of the inner dam portion 410. Accordingly, the first touch metal TM1 may not be disposed on the upper portion of the inner dam portion 410. However, the first touch metal TM1 may be disposed to extend without being disconnected at the upper portion of the inner dam portion 410.

Referring to FIG. 14, the first touch metal TM1 may not be disposed on the inner dam portion 410, but may extend from the outside of the inner dam portion 410 to the patterned first planarization layer 521. The first touch metal TM1 may be disposed under the outer dam portion 420.

Referring to FIG. 14, the first planarization layer 521 positioned at the innermost side among the patterned first planarization layers 521 is disposed adjacent to the first touch metal TM1. As an example, the first touch metal TM1 may be disposed to extend from the outside of the inner dam portion 410 to the area in which the patterned first planarization layer 521 is disposed.

The touch interlayer insulation layer 222 may be disposed on the first touch metal TM1 and the touch buffer layer 221. The touch interlayer insulation layer 222 may extend to pass through the upper portion of the inner dam portion 410 and the lower portion of the outer dam portion 420.

The touch interlayer insulation layer 222 may be disposed to cover the first touch metal TM1 and the touch buffer layer 221, and the touch interlayer insulation layer 222 may be disposed to overlap the two patterned first planarization layers 521.

The second touch metal TM2 may be disposed on the touch interlayer insulation layer 222. The layer on which the second touch metal TM2 is disposed may be referred to as a second touch metal layer.

The second touch metal TM2 may be electrically connected to the first touch metal TM1 in an area overlapping the first organic encapsulation layer 212. The second touch metal TM2 may be disposed in contact with the first touch metal TM1 through a contact hole of the touch interlayer insulation layer 222. Referring to FIG. 14, the second touch metal TM2 may be electrically connected to the first touch metal TM1 through two contact holes in an area overlapping the first organic encapsulation layer 212.

The second touch metal TM2 may be disposed to extend from an area overlapping the first organic encapsulation layer 212 to an area in which the patterned first planarization layer 521 is disposed. The second touch metal TM2 may extend to pass through the upper portion of the inner dam portion 410 and the lower portion of the outer dam portion 420.

The second touch metal TM2 may be electrically connected to the first touch metal TM1 between the inner dam portion 410 and the patterned first planarization layer 521. The second touch metal TM2 may be disposed in contact with the first touch metal TM1 through a contact hole of the touch interlayer insulation layer 222. Referring to FIG. 14, the second touch metal TM2 may be electrically connected to the first touch metal TM1 through four contact holes between the inner dam portion 410 and the patterned first planarization layer 521.

A valley may be formed between the two patterned first planarization layers 521. The second touch metal TM2 may be disposed to extend to the valley. The touch buffer layer 221 and the touch interlayer insulation layer 222 may be etched and removed in the area in which the valley is formed. In the corresponding area, the second touch metal TM2 may be disposed in contact with the second source drain metal.

The insulation layers 510 may include a lower end portion 510a and an upper end portion 510b. The gate metal 1414 may be disposed on the lower end portions 510a of the insulation layers 510. The upper end portions 510b of the insulation layers 510 may be disposed to cover the gate metal 1414.

The second source drain metal 1413 may be disposed in contact with the second touch metal TM2, and the second source drain metal 1413 may be disposed in contact with the gate metal 1414 beyond the patterned first planarization layer 521. A gate metal 1414 may be disposed inside the insulation layers 510. The gate metal 1414 may be disposed in contact with the second source drain metal 1413 through contact holes of the insulation layers 510.

The gate metal 1414 may be disposed to extend to the pad area. Two patterned first planarization layers 521 may be disposed in the pad area. The two patterned first planarization layers 521 may be disposed to be spaced apart from each other. In the pad area, a first source drain metal 1423 and a second source drain metal 1422 disposed on the first source drain metal 1423 may be disposed between the two patterned first planarization layers 521. The gate metal 1414 may be disposed in contact with the first source drain metal 1423 through contact holes of the plurality of inorganic layers. The first source drain metal 1423 may be disposed in contact with the second source drain metal 1422. A second touch metal TM2 may be further disposed on the two patterned first planarization layers 521, and the second touch metal TM2 may be disposed in contact with the second source drain metal 1422. Therefore, the second touch metal TM2 may be electrically connected to the second source drain metal 1422, the first source drain metal 1423, the gate metal 1414, and the first touch metal TM1.

The second touch metal TM2, the second source drain metal 1422, and the first source drain metal 1423 disposed in the pad area may constitute one touch pad TP. As an example, one touch pad TP may include a second touch metal TM2, a second source drain metal 1422, and a first source drain metal 1423.

Further, the touch line TL may include a gate metal 1414, a second touch metal TM2, and a first touch metal TM1. As an example, as the gate metal 1414, the second touch metal TM2, and the first touch metal TM1 are electrically connected to each other, the gate metal 1414, the second touch metal TM2, and the first touch metal TM1 may constitute the touch line TL.

The touch line TL may include a first line portion disposed on the inclined surface of the first organic encapsulation layer 212, a second line portion disposed on the inner dam portion 410, and a third line portion disposed under the outer dam portion 420.

The color filter buffer layer 251 may be disposed on the second touch metal TM2.

The color filter buffer layer 251 may extend to pass through the upper portion of the inner dam portion 410 and the lower portion of the outer dam portion 420.

The color filter buffer layer 251 may be disposed on the patterned first planarization layer 521.

After the color filter buffer layer 251 is disposed in the pad area, a partial area may be etched and removed. The touch pad TP may exchange signals with the outside through the area where the color filter buffer layer 251 has been removed.

The black matrix 252 may be disposed on the color filter buffer layer 251. The color filter 253 may be disposed to overlap a portion of the black matrix 252. The overcoat layer 254 may be disposed on the black matrix 252 and the color filter 253.

The outer dam portion 420 may be disposed on the color filter buffer layer 251. The outer dam portion 420 may be disposed outside the overcoat layer 254 to be spaced apart from the overcoat layer 254.

The outer dam portion 420 may include the same material as the material included in the overcoat layer 254. Further, the outer dam portion 420 may further include a material included in at least one of the black matrix 252 or the color filter 253. In this case, the height of the outer dam portion 420 may increase.

The outer dam portion 420 may include a first dam 621, a second dam 622, and a third dam 623.

The width of the third dam 623 may be larger than the widths of the first dam 621 and the second dam 622.

The second organic encapsulation layer 260 may be disposed on the overcoat layer 254.

The outer dam portion 420 may reduce or prevent the second organic encapsulation layer 260 from overflowing.

Exemplary embodiments of the disclosure described above are briefly described below.

According to exemplary embodiments of the disclosure, a display device may comprise a substrate including a display area and a non-display area outside the display area, a light emitting element disposed on the substrate, a first inorganic layer disposed on the light emitting element, a first organic layer disposed on the first inorganic layer, a second inorganic layer disposed on the first organic layer and extending to a side surface of the first organic layer, an inner dam portion disposed on the substrate, disposed outside the first organic layer, and disposed under at least one of the first inorganic layer and the second inorganic layer, a black matrix disposed on the second inorganic layer, a plurality of color filters disposed on the second inorganic layer, an overcoat layer disposed on the black matrix and the plurality of color filters, a second organic layer disposed on the overcoat layer and extending to an upper portion of the inner dam portion, and an outer dam portion disposed outside the second organic layer and including a material included in the overcoat layer.

The outer dam portion may include a first outer dam disposed outside the overcoat layer and disposed to be spaced apart from the overcoat layer, and a second outer dam disposed outside the first outer dam and spaced apart from the first outer dam. The second outer dam may have a width larger than the first outer dam.

The outer dam portion may include a first outer dam disposed outside the overcoat layer and disposed to be spaced apart from the overcoat layer. The first outer dam may include a first portion including a first material, and a second portion positioned on the first portion and including a second material different from the first material. The first material may be a material included in the black matrix or the color filter, and the second material may be a material included in the overcoat layer.

The outer dam portion may further include a second outer dam disposed outside the first outer dam and disposed to be spaced apart from the first outer dam. The second outer dam may include a third portion including a third material, and a fourth portion positioned on the third portion and including a fourth material different from the third material. The third material may be a material included in the black matrix or the color filter, and the fourth material may be a material included in the overcoat layer. The second outer dam may have a width larger than the first outer dam.

The first outer dam may further include a third portion between the first portion and the second portion. The third portion may include a third material different from the first material and the second material. The first material may be a material included in the black matrix. The third material may be a material included in the color filter. The second material may be a material included in the overcoat layer.

At least a portion of the black matrix may be disposed on the inner dam portion and overlaps the inner dam portion. At least a portion of the color filter may be disposed on the inner dam portion and overlap the inner dam portion.

At least one of the first inorganic layer and the second inorganic layer may include at least one first hole or at least one first recess positioned between the inner dam portion and the outer dam portion.

The outer dam portion may include a first outer dam disposed outside the inner dam portion, and a second outer dam disposed outside the first outer dam. At least one of the first inorganic layer and the second inorganic layer may include at least one second hole or at least one second recess positioned between the first outer dam and the second outer dam.

The display device may further comprise a touch sensor layer disposed between the second inorganic layer and the black matrix, and a third inorganic layer disposed between the touch sensor layer and the black matrix. The third inorganic layer may be disposed to extend through an upper portion of the inner dam portion to a lower portion of the outer dam portion.

The touch sensor layer may include a touch electrode disposed to overlap the black matrix, and a touch line extending from, or electrically connected to, the touch electrode. The touch line may be disposed to extend through an upper portion of the inner dam portion along an inclined surface of the first organic layer to a lower portion of the outer dam portion.

The touch sensor layer may include a first touch metal layer disposed on the second inorganic layer, a touch interlayer insulation layer disposed on the first touch metal layer, and a second touch metal layer disposed on the touch interlayer insulation layer and electrically connected to the first touch metal layer through a hole of the touch interlayer insulation layer.

The display device may further comprise a touch line electrically connected to the first touch metal layer and the second touch metal layer. The touch line may be disposed to extend through an upper portion of the inner dam portion along an inclined surface of the first organic layer to a lower portion of the outer dam portion. The touch line may include a first line portion disposed on an inclined surface of the first organic layer, a second line portion disposed on the inner dam portion, and a third line portion disposed under the outer dam portion.

The first line portion may be of a dual-line type including the first touch metal layer and the second touch metal layer. The second line portion may be of a single-line type including the second touch metal layer. The third line portion may be of a dual-line type including the first touch metal layer and the second touch metal layer.

The display device may further comprise a touch pad electrically connected to the touch line, and an insulation layer disposed under the third line portion. The touch line may further include a fourth line portion connecting the third line portion and the touch pad. The fourth line portion may include a line metal layer different from the first touch metal layer and the second touch metal layer. The line metal layer may be disposed between the substrate and the insulation layer.

The display device may further comprise a black bank disposed under the black matrix and overlapping the black matrix, an adhesive layer disposed on the second organic layer and including an anti-reflection material, and a cover window disposed on the adhesive layer. An opening of the black bank may have a size larger than a size of an opening of the black matrix.

Exemplary embodiments of the disclosure may provide a display device comprising a substrate including a display area and a non-display area outside the display area, a light emitting element disposed on the substrate, a plurality of encapsulation layers disposed on the light emitting element, an inner dam portion disposed in the non-display area, and an outer dam portion disposed in the non-display area and disposed further outside than the inner dam portion, wherein at least one of the plurality of encapsulation layers may be disposed to extend to an upper portion of the inner dam portion and a lower portion of the outer dam portion.

The plurality of encapsulation layers may include a first organic layer and a second organic layer disposed on the first organic layer. The display device may further comprise a bank disposed under the first organic layer and defining an emission area of the light emitting element, and an overcoat layer disposed between the first organic layer and the second organic layer. The inner dam portion may include a material included in the bank. The outer dam portion may include a material included in the overcoat layer.

The display device may further comprise a black matrix and a color filter disposed between the first organic layer and the overcoat layer. The outer dam portion, of the inner dam portion and the outer dam portion, may further include a material included in at least one of the black matrix and the color filter.

The plurality of encapsulation layers may further include a first inorganic layer disposed under the first organic layer and a second inorganic layer disposed between the first organic layer and the second organic layer. At least one of the first inorganic layer and the second inorganic layer may be disposed to extend to an upper portion of the inner dam portion and a lower portion of the outer dam portion.

At least one of the first inorganic layer and the second inorganic layer may include at least one hole or at least one recess between the inner dam portion and the outer dam portion.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed:

1. A display device, comprising:
a substrate including a display area and a non-display area outside the display area;
a light emitting element disposed on the substrate;
a first inorganic layer disposed on the light emitting element;
a first organic layer disposed on the first inorganic layer;
a second inorganic layer disposed on the first organic layer and extending to a side surface of the first organic layer;
an inner dam portion disposed on the substrate, disposed outside the first organic layer, and disposed under at least one of the first inorganic layer and the second inorganic layer;
an overcoat layer disposed on the second inorganic layer;
a second organic layer disposed on the overcoat layer and extending to an upper portion of the inner dam portion; and
an outer dam portion disposed outside the second organic layer.

2. The display device of claim 1, wherein the outer dam portion includes a material included in the overcoat layer.

3. The display device of claim 1, further comprising:
a black matrix disposed on the second inorganic layer; and
a plurality of color filters disposed on the second inorganic layer,
wherein the overcoat layer is disposed on the black matrix and the plurality of color filters.

4. The display device of claim 1, wherein the outer dam portion includes:
a first outer dam disposed outside the overcoat layer and disposed to be spaced apart from the overcoat layer; and
a second outer dam disposed outside the first outer dam and spaced apart from the first outer dam.

5. The display device of claim 3, wherein the outer dam portion includes a first outer dam disposed outside the overcoat layer and disposed to be spaced apart from the overcoat layer, wherein the first outer dam includes:
a first portion including a first material; and
a second portion positioned on the first portion and including a second material different from the first material, and
wherein the first material is a material included in the black matrix or the color filter, and the second material is a material included in the overcoat layer.

6. The display device of claim 5, wherein the outer dam portion further includes a second outer dam disposed outside the first outer dam and disposed to be spaced apart from the first outer dam, wherein the second outer dam includes:
a third portion including a third material; and
a fourth portion positioned on the third portion and including a fourth material different from the third material,
wherein the third material is a material included in the black matrix or the color filter, and the fourth material is a material included in the overcoat layer.

7. The display device of claim 4, wherein the second outer dam has a width larger than the first outer dam.

8. The display device of claim 5, wherein the first outer dam further includes a third portion between the first portion and the second portion,
wherein the third portion includes a third material different from the first material and the second material,
wherein the first material is a material included in the black matrix, and
wherein the third material is a material included in the color filter.

9. The display device of claim 3, wherein at least a portion of the black matrix is disposed on the inner dam portion and overlaps the inner dam portion, and
wherein at least a portion of the color filter is disposed on the inner dam portion and overlaps the inner dam portion.

10. The display device of claim 1, wherein at least one of the first inorganic layer and the second inorganic layer includes at least one first recess positioned between the inner dam portion and the outer dam portion.

11. The display device of claim 10, wherein the at least one of the first inorganic layer and the second inorganic layer includes a plurality of first recesses, and
wherein there is no dam portion between the plurality of first recesses.

12. The display device of claim 10, wherein the second organic layer is disposed in the at least one first recess.

13. The display device of claim 1, wherein the outer dam portion includes:
a first outer dam disposed outside the inner dam portion; and
a second outer dam disposed outside the first outer dam, and
wherein at least one of the first inorganic layer and the second inorganic layer includes at least one second recess positioned between the first outer dam and the second outer dam.

14. The display device of claim 12, wherein the at least one of the first inorganic layer and the second inorganic layer further includes at least one third recess positioned between the inner dam portion and the outer dam portion.

15. The display device of claim 3, further comprising:
a touch sensor layer disposed between the second inorganic layer and the black matrix; and
a third inorganic layer disposed between the touch sensor layer and the black matrix,
wherein the third inorganic layer is disposed to extend through an upper portion of the inner dam portion to a lower portion of the outer dam portion.

16. The display device of claim 15, wherein the touch sensor layer includes:
a touch electrode disposed to overlap the black matrix; and
a touch line extending from, or electrically connected to, the touch electrode, and
wherein the touch line is disposed to extend through an upper portion of the inner dam portion along an inclined surface of the first organic layer to a lower portion of the outer dam portion.

17. The display device of claim 15, wherein the touch sensor layer includes:
a first touch metal layer disposed on the second inorganic layer;
a touch interlayer insulation layer disposed on the first touch metal layer; and
a second touch metal layer disposed on the touch interlayer insulation layer and electrically connected to the first touch metal layer through a hole of the touch interlayer insulation layer.

18. The display device of claim 17, further comprising a touch line electrically connected to the first touch metal layer and the second touch metal layer,
wherein the touch line is disposed to extend through an upper portion of the inner dam portion along an inclined surface of the first organic layer to a lower portion of the outer dam portion, and wherein the touch line includes:
a first line portion disposed on an inclined surface of the first organic layer;
a second line portion disposed on the inner dam portion; and
a third line portion disposed under the outer dam portion.

19. The display device of claim 18, wherein the first line portion is of a dual-line type including the first touch metal layer and the second touch metal layer,
wherein the second line portion is of a single-line type including the second touch metal layer, and
wherein the third line portion is of a dual-line type including the first touch metal layer and the second touch metal layer.

20. The display device of claim 19, further comprising:
a touch pad electrically connected to the touch line; and
an insulation layer disposed under the third line portion,
wherein the touch line further includes a fourth line portion connecting the third line portion and the touch pad,
wherein the fourth line portion includes a line metal layer different from the first touch metal layer and the second touch metal layer, and
wherein the line metal layer is disposed between the substrate and the insulation layer.

21. The display device of claim 3, further comprising:
a black bank disposed under the black matrix and overlapping the black matrix,
wherein an opening of the black bank has a size larger than a size of an opening of the black matrix.

22. The display device of claim 1, wherein a height of an upper surface of the outer dam portion is the same as a height of an upper surface of the overcoat layer adjacent to the outer dam portion.

23. A display device, comprising:
a substrate including a display area and a non-display area outside the display area;
a light emitting element disposed on the substrate;
a plurality of encapsulation layers disposed on the light emitting element;
an inner dam portion disposed in the non-display area; and
an outer dam portion disposed in the non-display area and disposed further outside than the inner dam portion,
wherein at least one of the plurality of encapsulation layers is disposed to extend to an upper portion of the inner dam portion and a lower portion of the outer dam portion.

24. The display device of claim 23, wherein the plurality of encapsulation layers include a first organic layer and a second organic layer disposed on the first organic layer, wherein the display device further comprises:
a bank disposed under the first organic layer and defining an emission area of the light emitting element; and
an overcoat layer disposed between the first organic layer and the second organic layer,
wherein the inner dam portion includes a material included in the bank, and
wherein the outer dam portion includes a material included in the overcoat layer.

25. The display device of claim 24, further comprising a black matrix and a color filter disposed between the first organic layer and the overcoat layer,
wherein the outer dam portion, between the inner dam portion and the outer dam portion, further includes a material included in at least one of the black matrix and the color filter.

26. The display device of claim 24, wherein the plurality of encapsulation layers further include a first inorganic layer disposed under the first organic layer and a second inorganic layer disposed between the first organic layer and the second organic layer,
wherein at least one of the first inorganic layer and the second inorganic layer is disposed to extend to an upper portion of the inner dam portion and a lower portion of the outer dam portion.

27. The display device of claim 25, wherein at least one of the first inorganic layer and the second inorganic layer includes at least one recess between the inner dam portion and the outer dam portion.
